(19) United States
(12) Patent Application Publication
(10) Pub. No.: US 2026/0155626 A1
(43) Pub. Date: Jun. 4, 2026

(54) FREQUENCY COMB GENERATORS WITH ACTIVE OPTICAL CAVITIES

(71) Applicant: Mellanox Technologies, Ltd., Yokneam (IL)

(72) Inventors: Roy RUDNICK, Tel Aviv (IL); Isabelle CESTIER, Haifa (IL); Elad MENTOVICH, Tel Aviv (IL)

(21) Appl. No.: 18/968,118

(22) Filed: Dec. 4, 2024

(51) Int. Cl. H01S 5/10; H01S 5/0225; H01S 5/065; H01S 5/343

(52) U.S. Cl. CPC H01S 5/1071; H01S 5/0225; H01S 5/0657; H01S 5/1028; H01S 5/343

(57) ABSTRACT

Frequency comb generators are provided that include at least one of a closed loop formed of gain material, or a gain material section divided into two or more segments by one or more dividers, wherein at least one of the two or more segments is a tapered segment. A frequency comb generator is optically coupled to an output waveguide for providing frequency comb pulses generated by the frequency comb generator to one or more downstream elements.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. Wavelength division multiplexing (WDM) may be used to increase the density of interfaces between clusters of computing resources. WDM is conventionally accomplished using multiple distributed feedback (DFB) lasers. However, such implementations of WDM tend to have relatively large footprints and require substantial power consumption. Accordingly, a need exists for power efficient and size efficient optical sources for use in WDM applications.

### GENERAL DESCRIPTION

Datacenters rely on a fast and robust communication infrastructure. This is achieved by using optical interconnects, especially between different server racks. Each physical link employing a single optical fiber includes multiple communication channels, which are distinguished by different wavelengths in wavelength division multiplexing (WDM) systems.

The transmitters in optical WDM transceiver modules are typically based on arrays of discrete single wavelength lasers, such as the distributed feedback (DFB) lasers. However, in order to decrease power consumption and complexity, these lasers could be replaced by a single comb laser. The comb laser generates a range of discrete, equally spaced frequencies.

As transceivers increase their line bitrate, currently from 25 Gbit/s to 50 Gbit/s and then to 100 Gbit/s, as well as upgrade the modulation order from present techniques like non-return-to-zero (NRZ) to pulse amplitude modulation level 4 (PAM-4), the challenge is how to scale the power consumption by the laser sources because these increments require an increase in the signal-to-noise ratio (SNR) of the transmitter.

For example, when moving from NRZ to PAM-4 at the same bitrate, the SNR is reduced by a factor of 3. Therefore, the power needs to increase by a factor of 3 just to maintain the same bit error rate (BER) count as before.

When moving from a PAM-4 to PAM-8 (PAM level 8), both operating at the same bitrate, the SNR needs to be increased to ensure the PAM-8 signal reach the same BER as in the case of PAM-4.

Supporting a sustainable relation between SNR and BER typically requires increasing the available power provided by the laser source, which increases cost. As a result, lasers need to generate more light, which in turn, increases the power consumption above a linear scaling and introduces heat dissipation strain and thermal management challenges, at the same time.

This is particularly relevant for transceivers that need to be encapsulated in standardized pluggable forms, which have limited heat dissipation properties and small space, such that they rely on air flow design, thereby limiting the amount of power transceivers can take from the main rack by the form-factor standards.

Frequency comb generators seek to replace arrays of discrete laser sources with one single laser source. The light from the laser is subsequently split into several different light beams at different wavelengths, and each of these beams is used to convey an individual data stream.

Traditional frequency comb generators have been constructed using discrete components for applications that allow for a large footprint, such as in the fields of metrology and sensing. Such devices, however, are bulky and do not meet requirements for the integrated photonics challenge.

Various embodiments provide frequency comb generators with active optical cavities. In various embodiments, the frequency comb generators are monolithic and/or on-chip frequency comb lasers. This enables a frequency comb generator to be directly integrated with a photonic integrated circuit, for example. The laser pulses generated by the frequency comb generator comprise discrete and regularly spaced spectral lines or “teeth.” These spectral lines or teeth may be used to perform dense WDM, in some embodiments. The frequency comb generators is capable of making an affordable, efficient, high power with desirable mode spacing frequency comb source. Dense low-power interfaces are paramount to continue scaling AI/ML systems to interconnect large clusters (GPUs, CPUs, DPUs, . . . ). Compared to multiple DFB lasers implementation a monolithic frequency comb laser has a smaller footprint and lower power consumption.

In various embodiments, the frequency comb generator includes an active optical cavity. In some embodiments, the active optical cavity includes a ring-shaped or closed ring/loop of gain material. In some embodiments, the active optical cavity includes a generally linear cavity having a gain material section therein, where the gain material section is divided into segments and at least one of the segments is flared or tapered.

In certain applications, a frequency comb generator may be coupled to an output waveguide (e.g., directly, evanescently, and/or the like). The output waveguide may be used to optically couple the frequency comb generator to one or more modulators, multiplexers, a photonic integrated circuit (PIC), and/or the like. For example, the frequency comb generator may be part of an interconnect used for optical communications.

The present disclosure describes interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector. In some embodiments, the present disclosure provides optical interconnects for high bandwidth density applications like switches and GPUs.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

According to an aspect of the present disclosure, a frequency comb generator is provided. In an example embodiment, the frequency comb generator includes a closed ring or loop formed of gain material; and an output waveguide. The closed ring of gain material is configured to provide an optical cavity for generating frequency comb pulses and the output waveguide is evanescently coupled to the optical cavity.

In general, the closed ring or loop formed of gain material is formed on a substrate. The gain material comprises at least one of quantum dots, quantum dashes, or quantum wells of a III-V semiconductor material. The frequency comb generator may further include a first electrode and a second electrode wherein the closed ring or loop formed of gain material is disposed, at least in part, between the first electrode and the second electrode. In certain embodiments, the frequency comb pulses comprise a plurality of spectral lines characterized and/or separated from one another by a line spacing. In certain embodiments, the line spacing is at least 50 GHz. In some embodiments, the line spacing is at least 90 GHz. In some embodiments, the frequency comb generator further includes an anti-reflective coating applied to an output facet of the closed ring or loop formed of gain material.

In certain embodiments, the frequency comb generator includes a waveguide grating disposed within the closed ring or loop formed of gain material. The waveguide grating can be placed anywhere along the ring resonator. The waveguide grating may be configured to filter spectral lines present in the frequency comb pulses such as to reduce the number of spectral lines for example. In certain embodiments, the frequency comb generator further includes a saturable absorber disposed within the closed ring or loop formed of gain material. In certain embodiments, the saturable absorber is electrically isolated from the gain material (e.g., via trenches, implantation, and/or the like). In an example embodiment, the frequency comb generator includes at least two saturable absorbers within the closed loop formed of gain material that are evenly spaced about the closed loop formed of gain material such that the active optical cavity is configured for colliding pulse mode locking.

According to another aspect, a frequency comb generator is provided. In an example embodiment, the frequency comb generator includes a gain material section that extends along a gain axis from a first end to a second end. The gain material section is configured to be an optical cavity for generating frequency comb pulses. The optical cavity is characterized by a section length, and a distance from the first end to the second end is greater than the section length. The frequency comb generator further includes one or more dividers. The one or more dividers divide the gain material section into two or more segments where each segment of the two or more segments has an optical length that is an integer multiple of the section length. At least one segment has a width in a direction perpendicular to the gain axis that is non-constant along a length of the at least one segment, the length being along the gain axis.

In certain embodiments, the one or more dividers comprise at least one saturable absorber or at least one index gap. The frequency comb generator may further include a first confinement element disposed at the first end and a second confinement element disposed at the second end. The first confinement element may be a mirror and the second confinement element is one of a mirror or a saturable absorber. The second end of the gain material section is optically coupled to an output waveguide (e.g., via the second confinement element).

In certain embodiments, at least one segment of the two or more segments has a waveguide grating formed therein configured to filter spectral lines present in the frequency comb pulses.

In an example embodiment, the two or more segments are each configured to generate a selected harmonic mode of the gain material section such that the selected harmonic mode generated in adjacent segments of the two or more segments collide at a divider disposed between the adjacent segments to generate a primary mode of the gain material section.

In certain embodiments, the at least one segment having a width in a direction perpendicular to the gain axis that is non-constant along a length of the at least one segment is a tapered segment defined at least in part by a tapered boundary. The tapered boundary is one of a straight taper or an adiabatic taper.

According to another aspect, a system is provided. The system includes a substrate; a frequency comb generator formed on the substrate; an output waveguide optically coupled to the frequency comb generator; and one or more downstream elements. The output waveguide provides frequency comb pulses generated by the frequency comb generator to the downstream elements. The frequency comb generator includes one of a closed ring or loop formed of gain material, or a gain material section divided into two or more segments by one or more dividers, wherein at least one of the two or more segments is a tapered segment.

In an example embodiment, at least one of the one or more downstream elements is configured to perform dense wavelength division multiplexing using the frequency comb pulses.

### BRIEF DESCRIPTION OF THE SEVERAL VIEWS OF THE DRAWINGS

Reference will now be made to the accompanying drawings, which are not necessarily drawn to scale, and wherein:

FIG. 1 provides a top cross-sectional view of an example frequency comb generator including an active optical cavity including a gain material section characterized by closed loop/ring topology, in accordance with certain embodiments;

FIG. 1A provides a cross-sectional view taken along the line AA shown in FIG. 1, in accordance with certain embodiments;

FIG. 1B provides simulation results of the field within a closed loop active cavity, such as that shown in FIG. 1, in accordance with certain embodiments;

FIG. 2 provides a top cross-sectional view of another example frequency comb generator including an active optical cavity including a gain material section characterized by closed loop/ring topology, in accordance with certain embodiments;

FIG. 3 provides a top cross-sectional view of another example frequency comb generator including an active optical cavity including a gain material section characterized by closed loop/ring topology, in accordance with certain embodiments;

FIG. 4 provides a top cross-sectional view of an example frequency comb generator including an active optical cavity including a gain material section including at least one segment having a non-constant width, in accordance with certain embodiments;

FIG. 5 provides a top cross-sectional view of another example frequency comb generator including an active optical cavity including a gain material section including at least one segment having a non-constant width, in accordance with certain embodiments;

FIG. 6 provides a top cross-sectional view of another example frequency comb generator including an active optical cavity including a gain material section including at least one segment having a non-constant width, in accordance with certain embodiments;

FIG. 7 provides a top cross-sectional view of another example frequency comb generator including an active optical cavity including a gain material section including at least one segment having a non-constant width, in accordance with certain embodiments;

FIG. 7A provides a plot illustrating simulation results of output power of the frequency comb generator shown in FIG. 7, with respect to time;

FIG. 7B provides a plot illustrating simulation results of output power of an example frequency comb generator shown in FIG. 7C, with respect to time;

FIG. 7C illustrates an example colliding pulse mode locking frequency comb generator, in accordance with an example embodiment.

FIG. 8 provides a top cross-sectional view of another example frequency comb generator including an active optical cavity including a gain material section including at least one segment having a non-constant width, in accordance with certain embodiments;

FIG. 9 provides a top cross-sectional view of another example frequency comb generator including an active optical cavity including a gain material section including at least one segment having a non-constant width, in accordance with certain embodiments;

FIG. 10 provides a schematic illustration of an adiabatic taper, according to certain embodiments;

FIG. 11 provides a block diagram of an example system including a frequency comb generator, according to certain embodiments;

FIG. 11A provides a block diagram of an example N-channel system including a frequency comb generator, according to certain embodiments;

FIGS. 11B-11D show schematic diagrams of three examples of frequency comb generators implemented in multi-chip modules (MCM) where a first substrate or die houses the frequency comb generator and a second substrate or die houses silicon photonics elements, according to some embodiments of the current disclosure;

FIG. 12 provides a block diagram of an example system that may include one or more optical chips according to certain embodiments;

FIG. 13 provides a schematic diagram of an example datacenter that may include one or more optical chips according to certain embodiments; and

FIG. 14 provides a block diagram of two example communication devices in communication with one another according to certain embodiments.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide frequency comb generators with active optical cavities. An active optical cavity is an optical cavity where the gain material is disposed within the active optical cavity. In various embodiments, the frequency comb generators are monolithic and/or on-chip frequency comb lasers. This enables a frequency comb generator to be directly integrated with a photonic integrated circuit, for example. The laser/frequency comb pulses generated by the frequency comb generator comprise discrete and regularly spaced spectral lines or “teeth.” These spectral lines or teeth may be used to perform dense WDM, in some embodiments. For example, the frequency of an nth spectral line fₙ of a frequency comb pulse can generally be described as fₙ=f₀+n·fᵣ, where n is an integer, f₀ is the carrier offset frequency, and fᵣ is the comb tooth spacing. In certain embodiments (e.g., embodiments where the frequency comb generator is used as a laser source for dense WDM), the comb tooth spacing fᵣ is approximately 100 GHz or greater. For example, the comb tooth spacing fᵣ may be at least 50 GHz, or at least 90 GHz, in various embodiments.

In various embodiments, the frequency comb generator includes an active optical cavity. In some embodiments, the active optical cavity includes a ring-shaped or closed ring/loop of gain material. In certain embodiments, the gain material can be made of III-V quantum dots, quantum wells, quantum dashes on a III-V or Si substrate. An output waveguide or waveguide bus may be evanescently coupled to the ring to provide the laser/frequency comb pulses to an optical system such as a modulator, multiplexer, optical chip, optical interconnect, and/or the like. The output waveguide or waveguide bus may be configured to couple out a selected portion of the optical power from the active optical cavity that is less than 100%. The portion of the optical power that is not coupled out from the active optical cavity provides a feedback mechanism for mode coupling within the active optical cavity.

In some embodiments, the active optical cavity includes a generally linear cavity having a gain material section therein, where the gain material section is divided into segments and at least one of the segments is flared or tapered. For example, the active optical cavity includes a gain material section and at least one divider that devices the gain material section into two or more segments. The at least one divider may be a saturable absorber, index gap, and/or other element that results in partial and/or selective optical confinement within the corresponding segment(s). The active optical cavity may further comprise or be defined by confinement elements disposed at opposite ends of the gain material section (along the gain axis of the gain material section). For example, the confinement elements may include mirrors, saturable absorbers, and/or the like.

In certain applications, a frequency comb generator may be coupled to an output waveguide (e.g., directly, evanescently, and/or the like). The output waveguide may be used to optically couple the frequency comb generator to one or more modulators, multiplexers, a photonic integrated circuit (PIC), and/or the like. For example, the frequency comb generator may be part of an interconnect used for optical communications.

Wavelength division multiplexing (WDM) is used in various optical communications system to increase the density of interfaces between clusters of computing resources, for example. WDM is conventionally accomplished using multiple distributed feedback (DFB) lasers. However, such implementations of WDM tend to have relatively large footprints and require substantial power consumption.

According to various embodiments, a frequency comb generator is used to generate and provide a frequency comb (laser pulses comprising discrete and regularly spaced spectral lines or “teeth”) that may be used for WDM such as dense WDM (DWDM). DWDM is a form of WDM that multiplexes a plurality of wavelengths with adjacent wavelengths separated by about 100 GHz (e.g., approximately 0.8 nm), for example, when operating in the O band (˜1310 nm). Conventional frequency comb generators include an external high-power laser coupled to a non-linear high quality (high-Q) passive optical ring. However, such frequency comb generators require an external laser configured to provide very high optical power and suffer from lossy coupling to the ring resonator. Another conventional frequency comb generator is a Fabry Perot cavity laser combined with a saturable absorber forming a mode-locked laser. Such frequency comb generators require two electrical connections (one for the gain material and another for the saturable absorber) and have a specific range of driving current values and voltages that are able to give rise to frequency comb generation. Another conventional frequency comb generator is a self-mode locking Fabry Perot laser using quantum dot-based gain material. However, such frequency comb generators tend to be unpredictable and mode locking only occurs under specific initial conditions. Therefore, technical problems exist regarding providing frequency comb generators that are predictable, reliable, and energy/electrical power efficient.

Various embodiments provide technical solutions to these technical problems. Various embodiments provide frequency comb generators that have active optical cavities. An active optical cavity is an optical cavity having a gain material disposed within the active optical cavity. In some embodiments, the active optical cavity is a closed loop or ring. For example, the gain material may be formed in a closed loop or ring such that modes that are resonant with the closed loop or ring are generated. Amplification occurs within the cavity, which results in an improved signal (e.g., mode power) to noise ratio, compared to conventional frequency comb generators that use an external semiconductor optical amplifier. Such embodiments provide frequency comb generators that are electrical power efficient (e.g., may be operated using a conventional all plug, having better wall plug efficiency), stable/predictable, and may be implemented with a variety of gain materials (e.g., quantum wells, quantum dashes, and/or quantum dots) because there is no need for high-power laser and high Q factor external ring resonator.

In some embodiments, the active optical cavity includes a gain material section that extends along a gain axis and that is divided into segments (e.g., by saturable absorbers, refractive index gaps, and/or the like). At least one of the segments has a width in a direction transverse to the gain axis that is non-constant. For example, at least one of the segments may be flared or tapered. The division of the gain material section into segments results in colliding pulse mode locking and coupled cavity harmonic locking increasing the total length and gain of the device. Moreover, the flared or tapered segments of the gain material section provide for more efficient generation of optical power for large mode spacing with high power wand less susceptibility to temperature fluctuations. Amplification occurs within the cavity, which results in an improved signal to noise ratio, compared to conventional frequency comb generators that use an external semiconductor optical amplifier. The modal gain per round trip is R₁ R₂ e^{G2L}, where R₁ and R₂ are the facet reflectance, G is the modal gain including mode propagation loss and L is the cavity length. As mode spacing increases cavity length and gain decrease, resulting in lower optical power (overall and per line). It also impacts the fabrication tolerances as the device becomes smaller. To overcome the power loss a solution is to add a semiconductor optical amplifier (SOA) at the output of the comb source that needs an additional electrical connection, introduces additional noise, and has performance disadvantages. Such embodiments provide frequency comb generators that are electrical power efficient (e.g., may be operated using a conventional all plug), stable/predictable, may be implemented with a variety of gain materials (e.g., quantum wells, quantum dashes, and/or quantum dots), and that are less susceptible to temperature fluctuations, compared to conventional frequency comb generators.

Therefore, various embodiments provide technical improvements to the fields of frequency comb generators, WDM systems that may use frequency comb generators as a laser source, and/or related systems.

Example Frequency Comb Generator with a Closed Ring of Gain Material

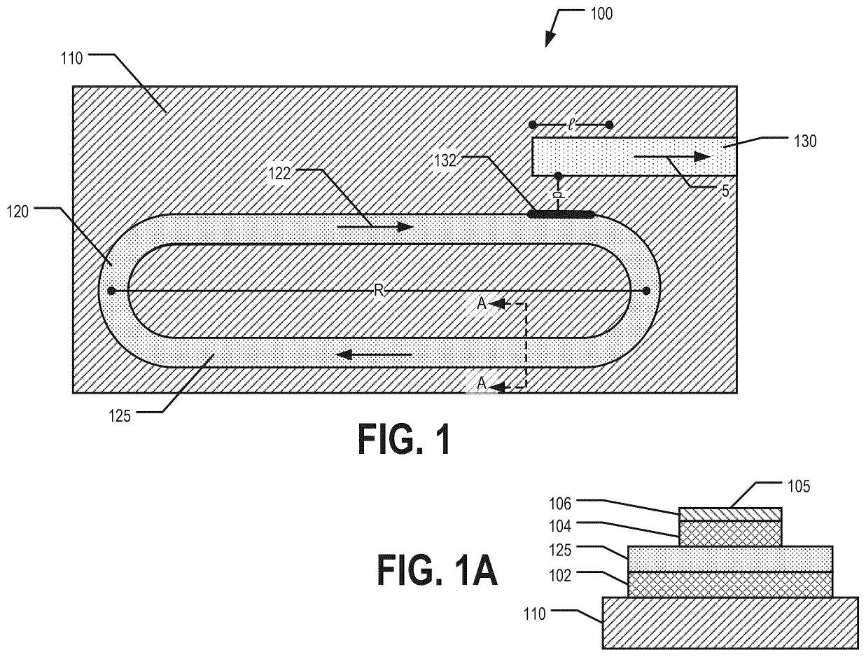

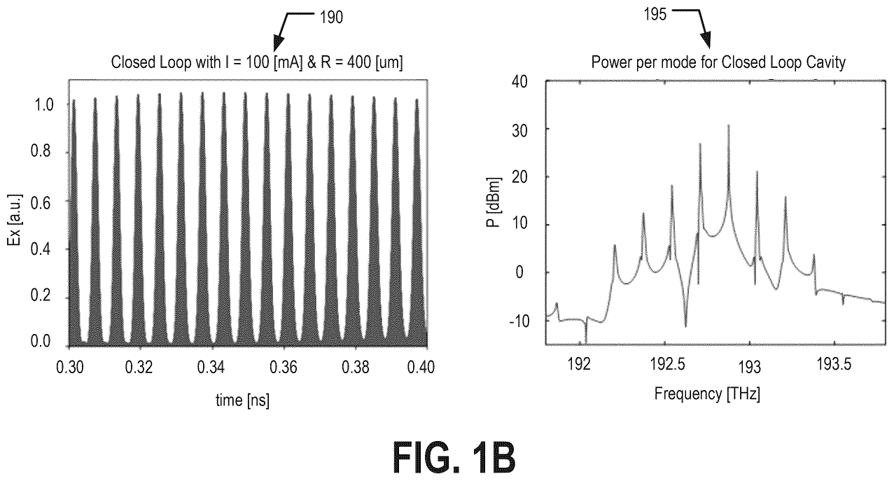

FIGS. 1, 2 and 3 illustrate top cross-sectional views of example frequency comb generators 100, 200, 300 that include an active optical cavity 120, 220, 320 including a closed ring or loop formed of gain material 125, 225, 325. The active optical cavity 120, 220, 320 is evanescently coupled to an output waveguide or waveguide bus (passive waveguide coupler) 130, 230, 330. In some embodiments, and as shown in this illustrative example, the bus waveguides 130, 230, 330 are linear (e.g., horizontal) waveguides. However, the bus waveguides 130, 230, 330 can have any suitable shape in accordance with embodiments described herein. In certain embodiments, the frequency comb generator includes two or more output waveguides or waveguide buses that are each optically (e.g., evanescently) coupled to the closed ring or loop formed of gain material and configured to provide frequency comb pulses to one or more downstream elements.

The waveguides 130, 230, 330 can be formed from any suitable material that has properties (e.g., index of refraction) to enable the optical coupling of light having the resonant wavelength within the closed ring or loop formed of gain material 125, 225, 325. In some embodiments, the waveguides 130, 230, 330 are formed from a semiconductor material. For example, the waveguides 130, 230, 330 can be formed from silicon (Si). Alternatively, at least one of the waveguides 130, 230, 330 can be formed from a different material.

Starting with FIG. 1, the frequency comb generator 100 is formed on a substrate 110. The frequency comb generator 100 includes an active optical cavity 120 and an output waveguide or waveguide bus 130. The active optical cavity comprises a closed ring or loop formed of gain material 125. In various embodiments, the substrate 110 is a silicon substrate, III-V semiconductor substrate, silica substrate, a silica layer on a silicon substrate, germanium substrate, gallium nitride substrate, and/or another substrate appropriate for the application. The gain material 125 may comprise a III-V semiconductor material, such as GaAs; InP; InAs; GaN; InGaAs; or ternary and/or quaternary compounds with Ga, In, As, and/or P, for example. In various embodiments, the gain material 125 comprises quantum wells, quantum dashes, quantum dots, and/or the like. In various embodiments, the gain material may be configured to provide laser/frequency comb pulses having one or more spectral lines within a selected wavelength range or frequency band.

In various embodiments, the gain material 125 is patterned to provide a closed loop or ring of gain material. For example, the gain material 125 may be patterned such that optical modes that are resonant with the active optical cavity 120 are amplified as the modes travel around the closed ring or loop, as indicated by arrows 122 showing the propagation direction of the output comb lines coupled to the output waveguide 130. Non-resonant optical modes are dampened via destructive interference. For example, the closed loop or ring of gain material 125 may be a ring resonator.

In an example embodiment, the active optical cavity 120 is characterized by a cavity length of 2R, where R is the leg length of the active optical cavity 120 (e.g., the length along the surface of the substrate 110 that the active optical cavity 120 extends). In various embodiments, leg length R of the active optical cavity 120 is in a range of 100 to 1000 microns. For example, the leg length R of the active optical cavity 120 is in a range of 200-600 microns, in some embodiments.

In some embodiments, as shown in FIG. 1A, the closed ring or loop of gain material 125 is disposed between a first electrode 102 and a second electrode 104. For example, the first electrode 102 may be formed on the substrate 110, the gain material 125 may be formed at least in part on the first electrode 102, the second electrode 104 may be formed on the gain material 125, and an electrode pad 106 may be formed on the second electrode 104. Application or injection of current or voltage to the first electrode 102 and/or the second electrode 104 causes the gain material to generate photons within the active optical cavity 120. In various embodiments, the first electrode 102 and the second electrode 104 comprise a conductive material such as a metal or another appropriate material.

In various embodiments, the first electrode 102 and the second electrode 104 are oppositely doped materials. In an example embodiment, the first electrode 102 comprises an n-doped material and/or is a portion of the substrate 110 that is n-doped and the second electrode comprises a p-doped material. In another example embodiment, the first electrode 102 comprises a p-doped material and/or is a portion of the substrate 110 that is p-doped and the second electrode comprises an n-doped material.

In an example embodiment, the first electrode 102 is configured to be placed into electrical communication with an electrical current or voltage source (or local ground) via a lead formed on or in the substrate 110, a through via through the substrate 110, and/or the like. In an example embodiment, the second electrode 104 may be configured to be placed into electrical communication with an electrical current or voltage source (or local ground) via the electrode pads 106. For example, an electrical lead or other electrical contact may be formed between the exposed surface 105 of the electrode pad 106 and a voltage and/or current source to apply an electrical current and/or voltage to the second electrode 104. In an example embodiment, the frequency comb generator 100 may be operated using (e.g., by applying to the first electrode 102 or the second electrode 104) a current in a range of 50 to 500 mA (e.g., 90-200 mA).

In various embodiments, the closed ring or loop of gain material 125 is evanescently coupled to an output waveguide or waveguide bus 130. In certain embodiments, the output waveguide or waveguide bus 130 is a silica waveguide or other type of waveguide appropriate for the application. The output waveguide or waveguide bus 130 is configured to couple more than 0% and less than 100% (e.g., between 1% and 99%) of the optical power out of the active optical cavity 120. For example, the distance d between the active optical cavity 120 and the output waveguide or waveguide bus 130 and/or the overlap length [symbol] configured to describe the length of the output waveguide and/or waveguide bus 130 that extends alongside the active optical cavity 120 may be configured to control the percentage (e.g. from 1 to 99 percent) or fraction of optical power that is coupled out of the active optical cavity 120 to ensure stable mode locking and sufficient output power for the application. The output waveguide or waveguide bus 130 may provide or guide the laser/frequency comb pulse 5 to a downstream element of the system including the frequency comb generator 100.

In various embodiments, the spectral lines of the frequency comb pulse to be used for a particular application (e.g., DWDM) are coupled out of the closed ring or loop of gain material 125 through the waveguide 130 (e.g., to be provided to one or more downstream elements) and at least a portion of the spectral lines not to be used in the particular application are coupled back into the active optical cavity 120 but propagating in an opposite direction (e.g., counter-clockwise for the scenario illustrated in FIG. 1). In some embodiments, the overlap length [symbol] is configured to cause phase shifting and/or introduce interference into the active optical cavity 120.

In an example embodiment, an anti-reflective coating 132 may be applied to an output facet of the closed ring or loop of gain material 125. For example, the anti-reflective coating may enable more efficient evanescent coupling between the output facet of the closed ring or loop of gain material 125 and the output waveguide or waveguide bus 130.

FIG. 1B provides simulation results of the field inside a closed loop active optical cavity 120 (e.g., a quantum dot ring resonator) with an active optical cavity driven with a current of 100 mA and having a leg length of R=400 microns. Plot 190 shows the extracted power (in arbitrary units a.u.) with respect to time of the frequency comb generator 100, showing the that closed loop active optical cavity 120 provides a pulsed source which, in the frequency domain, is a frequency comb. Plot 195 illustrates the power per mode of the closed loop active optical cavity 120 showing the spectral lines of the frequency comb, for an example embodiment.

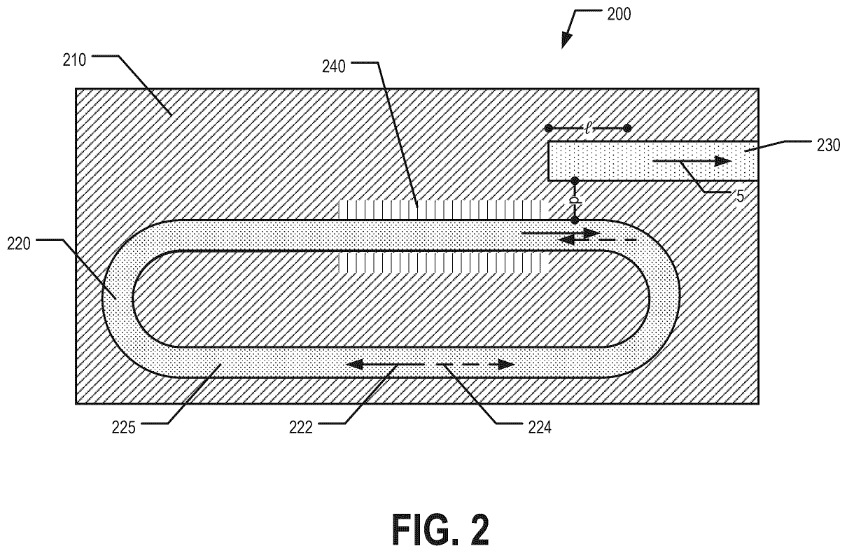

The example frequency comb generator 200 illustrated in FIG. 2 is formed on a substrate 210. The frequency comb generator 200 includes an active optical cavity 220 and an output waveguide or waveguide bus 230. The active optical cavity comprises a closed ring or loop formed of gain material 225. The frequency comb generator 200 is similar to the example frequency comb generator 100, but illustrates an example where the frequency comb generator includes a waveguide grating 240 formed and/or disposed within the closed loop or ring of gain material 225.

In various embodiments, the substrate 210 is a silicon substrate, III-V semiconductor substrate, silica substrate, a silica layer on a silicon substrate, germanium substrate, gallium nitride substrate, and/or another substrate appropriate for the application. The gain material 225 may comprise a III-V semiconductor material, such as GaAs; InP; InAs; GaN; InGaAs; or ternary and/or quaternary compounds with Ga, In, As, and/or P, for example. In various embodiments, the gain material 225 comprises quantum wells, quantum dashes, quantum dots, and/or the like. In various embodiments, the gain material may be configured to provide laser/frequency comb pulses having one or more spectral lines within a selected wavelength range or frequency band.

In various embodiments, the gain material 225 is patterned to provide a closed loop or ring of gain material. For example, the closed loop or ring of gain material 225 may be a ring resonator. A waveguide grating 240 is fabricated and/or disposed within the closed ring or loop of gain material 225. For example, the waveguide grating 240 is configured to filter specific wavelengths such that the specific wavelengths may be used to power the four-wave mixing comb generation process within the closed loop or ring of gain material 225.

The waveguide grating 240 may be placed at any location or position around the closed loop or ring of gain material 225. The location or position of the waveguide grating 240 around the closed loop or ring of gain material 225 may be selected based on a desired effect of the waveguide grating 240. For example, the location or position of the waveguide grating 240 around the closed loop or ring of gain material 225 may be selected to provide a desired direction of propagation and/or to affect the gain section length.

The spectral lines of the specific wavelengths to be used to power the four-wave mixing comb generation process within the closed loop or ring of the gain material 225 may traverse the closed loop or ring in a first direction 222 and the wavelengths filtered out by the waveguide grating 240 may traverse the closed loop or ring in a second direction 224. The first direction 222, in the portion of the closed loop or ring of gain material closest to the output waveguide or waveguide bus 230 corresponds to and/or is substantially parallel to the direction the laser/frequency comb pulse will travel along the output waveguide or waveguide bus 230. The first direction 222 is substantially opposite the second direction 224.

In an example embodiment, the active optical cavity 220 is characterized by a cavity length of 2R, where R is the leg length of the active optical cavity 220 (e.g., the length along the surface of the substrate 210 that the active optical cavity 220 extends). In various embodiments, leg length R of the active optical cavity 220 is in a range of 100 to 1000 microns. For example, the leg length R of the active optical cavity 220 is in a range of 200-600 microns, in some embodiments.

In some embodiments, the closed ring or loop of gain material 225 is disposed between a first electrode and a second electrode, similar to as shown in FIG. 1A. For example, the first electrode may be formed on the substrate 210, the gain material 225 may be formed at least in part on the first electrode, and the second electrode may be formed on the gain material 225. Application of current or voltage to the first electrode and/or the second electrode causes the gain material to generate photons within the active optical cavity 220. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 210, a through via through the substrate 210, and/or the like. In an example embodiment, the second electrode is configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 200 may be operated using a current in a range of 50 to 500 mA (e.g., 90-200 mA).

In various embodiments, the closed ring or loop of gain material 225 is evanescently coupled to an output waveguide or waveguide bus 230. In certain embodiments, the output waveguide or waveguide bus 230 is a silica waveguide or other type of waveguide appropriate for the application. The output waveguide or waveguide bus 230 is configured to couple more than 0% and less than 100% (e.g., between 1% and 99%) of the optical power of the selected wavelengths out of the active optical cavity 220. For example, the distance d between the active optical cavity 220 and the output waveguide or waveguide bus 230 and/or the overlap length [symbol] configured to describe the length of the output waveguide and/or waveguide bus 230 that extends alongside the active optical cavity 220 may be configured to control the percentage or fraction of optical power that is coupled out of the active optical cavity 220. The output waveguide or waveguide bus 230 may provide or guide the laser/frequency comb pulse 5 to a downstream element of the system including the frequency comb generator 200.

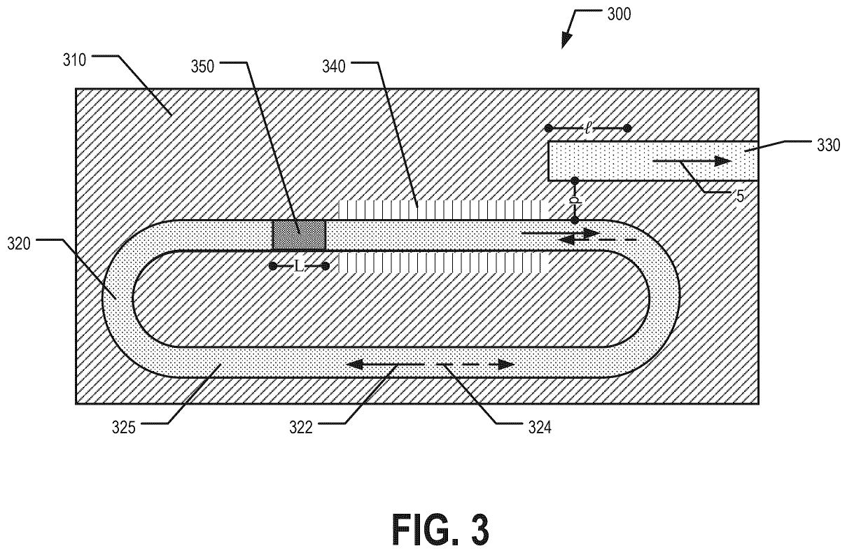

The example frequency comb generator 300 illustrated in FIG. 3 is formed on a substrate 310. The frequency comb generator 300 includes an active optical cavity 320 and an output waveguide or waveguide bus 330. The active optical cavity comprises a closed ring or loop formed of gain material 325. The frequency comb generator 300 is similar to the example frequency comb generator 200, but illustrates an example where the frequency comb generator further includes a saturable absorber (SA) 350 formed (e.g. embedded) and/or disposed within the active optical cavity 320. In some embodiments, the frequency comb generator includes an SA formed and/or disposed within the active optical cavity and does not include a waveguide grating.

In various embodiments, the substrate 310 is a silicon substrate, III-V semiconductor substrate, silica substrate, a silica layer on a silicon substrate, germanium substrate, gallium nitride substrate, and/or another substrate appropriate for the application. The gain material 325 may comprise a III-V semiconductor material, such as GaAs; InP; InAs; GaN; InGaAs; or ternary and/or quaternary compounds with Ga, In, As, and/or P, for example. In various embodiments, the gain material 325 comprises quantum wells, quantum dashes, quantum dots, and/or the like. In various embodiments, the gain material may be configured to provide laser/frequency comb pulses having one or more spectral lines within a selected wavelength range or frequency band.

In various embodiments, the gain material 325 is patterned to provide a closed loop or ring of gain material. For example, the closed loop or ring of gain material 325 may be a ring resonator. In various embodiments, the active optical cavity 320 includes a SA 350. For example, an SA 350 may be disposed within the closed loop or ring of gain material 325. In certain embodiments, an SA 350 is an optical device that reduces its absorption of light as the intensity of the light increases. For example, the SA 350 may comprise gain material 325 that is biased in an opposite direction from a remainder of the gain material 325 of the closed loop or ring of gain material 325. In certain embodiments, the SA 350 is electrically isolated from the gain material 325 via trenches, implantation, and/or the like, and is reverse biased with respect to the gain material 325. In various embodiments, the SA 350 is configured to assist in mode locking within the active optical cavity 320.

Depending on the respective locations and/or positions of the SA 350, waveguide grating 340, and output waveguide or waveguide bus 330, the SA 350 will be saturated by different spectrums. In certain embodiments, the respective locations and/or positions of the SA 350, waveguide grating 340, and output waveguide or waveguide bus 330, the SA 350 are configured to such that the SA 350 is saturated by selected spectral lines. For example, in certain embodiments, the SA 350 is disposed between the output waveguide or waveguide bus 330 and the waveguide grating 340, only the spectral lines to be used for the particular application (e.g., DWDM) will saturate the SA 350. Such a configuration provide improved wall plug efficiency and better a signal-to-noise ratio (SNR). In the example embodiment illustrated in FIG. 3, the grating 340 is disposed between the SA 350 and the output waveguide or the waveguide bus 330 and all of the spectral components (e.g., all of the spectral lines) will saturate the SA 350 providing highly stable mode locking.

Including an SA 350 in an active optical cavity 320 including a closed loop or ring of gain material 325 is preferable compared to a Fabry Perot cavity with a saturable absorber because the gain section of the closed loop or ring of gain material 325 is longer than a Fabry Perot cavity of the same length (leg length R) and therefore will yield higher power. In addition, the illustrated frequency comb generator 300 is preferable compared to a Fabry Perot cavity with saturable absorber and semiconductor optical amplifier (SOA) for high power applications because in frequency comb generator 300, the amplification of the laser/frequency comb is within the active optical cavity 320 and will have less noise compared to the SOA configuration.

In some embodiments, waveguide grating 340 is fabricated and/or disposed within the closed ring or loop of gain material 325. For example, the waveguide grating 340 is configured to filter specific wavelengths such that the specific wavelengths may be used to power the four-wave mixing comb generation process within the closed loop or ring of gain material 325.

The waveguide grating 340 may be placed at any location or position around the closed loop or ring of gain material 325. The location or position of the waveguide grating 340 around the closed loop or ring of gain material 325 may be selected based on a desired effect of the waveguide grating 340.

The spectral lines of the specific wavelengths to be used to power the four-wave mixing comb generation process within the closed loop or ring of the gain material 325 may traverse the closed loop or ring in a first direction 322 and the wavelengths filtered out by the waveguide grating 340 may traverse the closed loop or ring in a second direction 324. The first direction 322, in the portion of the closed loop or ring of gain material closest to the output waveguide or waveguide bus 330 corresponds to and/or is substantially parallel to the direction the laser/frequency comb pulse will travel along the output waveguide or waveguide bus 330. The first direction 322 is substantially opposite the second direction 324.

In an example embodiment, the active optical cavity 320 is characterized by a cavity length of 2R, where R is the leg length of the active optical cavity 320 (e.g., the length along the surface of the substrate 310 that the active optical cavity 320 extends). In various embodiments, leg length R of the active optical cavity 320 is in a range of 100 to 1000 microns. For example, the leg length R of the active optical cavity 320 is in a range of 200-600 microns, in some embodiments.

In some embodiments, the closed ring or loop of gain material 325 is disposed between a first electrode and a second electrode, similar to as shown in FIG. 1A. For example, the first electrode may be formed on the substrate 310, the gain material 325 may be formed at least in part on the first electrode, and the second electrode may be formed on the gain material 325. Application of current or voltage to the first electrode and/or the second electrode causes the gain material to generate photons within the active optical cavity 320. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 310, a through via through the substrate 310, and/or the like. In an example embodiment, the second electrode may be configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 200 may be operated using a current in a range of 50 to 500 mA (e.g., 90-200 mA).

In some embodiments, frequency comb generator 300 may include third and fourth electrodes that are disposed on opposite sides of the SA 350 (in a configuration similar to the positioning of the first electrode 102 and the second electrode 104 with respect to gain material 125 as shown in FIG. 1A) and configured to be placed in electrical communication with respect current and/or voltage sources (or local ground) and configured to reverse bias the SA 350 (compared to a remainder of the closed loop or ring of gain material 325). For example, the third electrode may be formed on the substrate 310, the SA 350 may be formed at least in part on the third electrode, and the fourth electrode may be formed on the SA 350.

In an example embodiment, the frequency comb generator 300 includes at least two saturable absorbers 350 within the closed loop formed of gain material 325. The at least two saturable absorbers 350 are evenly spaced about the closed loop formed of gain material 125 such that the active optical cavity 320 is configured for colliding pulse mode locking.

In various embodiments, the closed ring or loop of gain material 325 is evanescently coupled to an output waveguide or waveguide bus 330. In certain embodiments, the output waveguide or waveguide bus 330 is a silica waveguide or other type of waveguide appropriate for the application. The output waveguide or waveguide bus 330 is configured to couple more than 0% and less than 100% (e.g., between 1% and 99%) of the optical power of the selected wavelengths out of the active optical cavity 320. For example, the distance d between the active optical cavity 320 and the output waveguide or waveguide bus 330 and/or the overlap length [symbol] configured to describe the length of the output waveguide and/or waveguide bus 330 that extends alongside the active optical cavity 320 may be configured to control the percentage or fraction of optical power that is coupled out of the active optical cavity 320. The output waveguide or waveguide bus 330 may provide or guide the laser/frequency comb pulse 5 to a downstream element of the system including the frequency comb generator 300 showing the propagation direction of the useful comb lines coupled to the output waveguide.

Example Frequency Comb Generator with a Tapered Segmented Gain Material Section

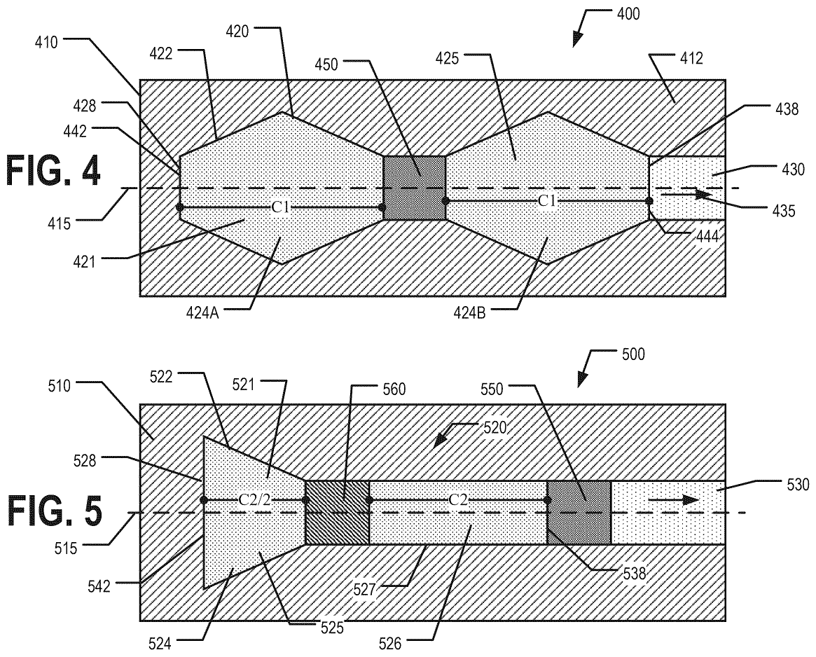

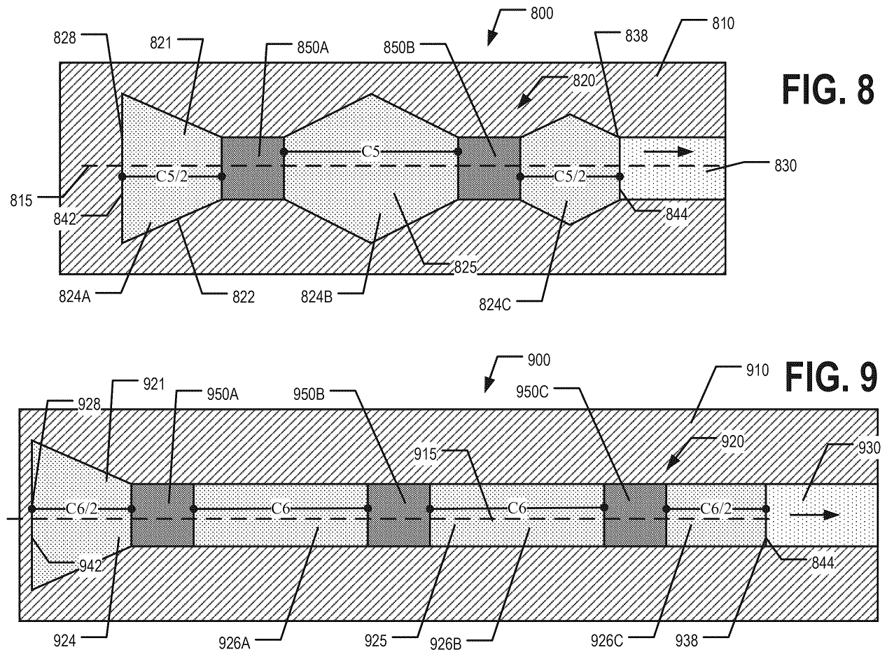

FIGS. 4-9 illustrate some example embodiments of frequency comb generators 400, 500, 600, 700, 800, 900 that include respective active optical cavities 420, 520, 620, 720, 820, 920. Each active optical cavity includes a respective gain material section 421, 521, 621, 721, 821, 921 that is divided into two or more segments by one or more dividers (e.g., saturable absorbers (SAs) 450, 550, 650, 750, 850, 950, refractive index gaps 560, and/or the like). At least one of segments of gain material sections is a flared or tapered segment 424, 524, 624, 724, 824, 924. A flared or tapered segment has a width in a direction transverse to the gain axis 415, 515, 615, 715, 815, 915 of the gain material section that is non-constant along the length of the segment in a direction parallel to the gain axis.

FIG. 4 illustrates a frequency comb generator 400 comprising an active optical cavity 420. The active optical cavity 420 is formed on a substrate 410. In various embodiments, the substrate 410 is a silicon substrate, III-V semiconductor substrate, silica substrate, a silica layer on a silicon substrate, germanium substrate, gallium nitride substrate, and/or another substrate appropriate for the application.

In various embodiments, the active optical cavity 420 includes a gain material section 421. In various embodiments, the gain material section 421 extends along a gain axis 415 from a first end 428 to second end 438. In some embodiments, confinement elements such as mirrors 442, 444 are located and/or disposed at the first end 428 and at the second end 438 to define the active optical cavity 420. In an example embodiment, a first mirror 442 disposed at the first end 428 of the gain material section 421 is configured to be a high reflectivity mirror. For example, the first mirror 442 may be configured to have a reflectivity of greater than 50% and possibly approaching 100% for light in a selected wavelength range or frequency band. In some embodiments, the frequency comb generator 400 does not include mirrors 442, 444. For example, a ridge waveguide is disposed on the gain material section 421 and, in certain embodiments, optical confinement within the ridge waveguide is achieved using changes in the refractive index of the ridge waveguide.

In various embodiments, the gain material section 421 comprises gain material 425. The gain material may be a III-V semiconductor material such as GaAs; InP; InAs; GaN; InGaAs; or ternary and/or quaternary compounds with Ga, In, As, and/or P, for example, and comprise quantum wells, quantum dashes, quantum dots, and/or the like. In various embodiments, the gain material may be configured to provide laser/frequency comb pulses having one or more spectral lines within the selected wavelength range or frequency band.

In various embodiments, the gain material section 421 is divided into two or more segments by at least one divider (e.g., SA, index gap, and/or the like). For example, the one or more dividers cause at least some optical confinement within respective segments defined at least in part by the dividers. For example, SA 450 divides the gain material section 421 into a first flared or tapered segment 424A and a second flared or tapered segment 424B. For example, the SA 450 may comprise gain material 425 that is biased in an opposite direction (e.g., reverse biased) from a remainder of the gain material 425 of the gain material section 421.

As used herein, a flared or tapered segment is a segment of a gain material section where the width of the segment measured in a direction transverse and/or perpendicular to the gain axis and in a plane parallel to a surface plane defined by a surface of the substrate hosting the frequency comb source, is non-constant along a length of the segment measured in a direction parallel to the gain axis. For example, the width of the first flared or tapered segment 424A in a direction transverse to the gain axis 415 and parallel to the surface 412 of the substrate 410 is non-constant along the length of the first flared or tapered segment 424A in a direction that is parallel to the gain axis 415. For example, the first flared or tapered segment 424A is defined, in part, by a flared or tapered boundary 422 which is not parallel to the gain axis 415. For example, the flared or tapered boundary 422 may form an angle with a line parallel to the gain axis 415 that is greater than 1 degree, in certain embodiments. In some embodiments, the flared or tapered boundary 422 forms an angle with a line parallel to the gain axis 415 that is greater than 3 degrees and less than 90 degrees. In an example embodiment, the gain material section 421 exhibits a folding symmetry across the gain axis 415.

A flared or tapered segment includes a larger area (e.g., in a plane parallel to the surface 412 of the substrate 410) than a segment of the same length that is not flared or tapered. This enables a flared or tapered segment to generate more optical power with application of a smaller current thereto, compared to a segment of the same length that is not flared or tapered.

In various embodiments, the active optical cavity 420 is characterized by a section length C1. The distance from the first end 428 of the gain material section 421 and the second end 438 of the gain material section (along the gain axis 415) is greater than the section length C1. In certain embodiments, each segment of the gain material section 421 has a length along the gain axis 415 that is equal to the section length C1. For example, the active optical cavity 420 is configured to generate optical modes in each segment of the gain material section 421 that are characterized by a wavelength equal to the section length C1 and/or harmonics thereof (e.g., C1/2, C1/4, etc.). The optical modes meet at the SA 450, causing the SA 450 to saturate more quickly than if an optical mode was incident on the SA 450 from only one direction, resulting in shorter pulses (compared to if an optical mode was incident on the SA 450 from only one direction) and assisting in mode locking.

The frequency comb generator 400 is a colliding pulse mode (CPM) locking source configured to use harmonic mode locking using a second harmonic mode (any harmonic can be used) of the active optical cavity 420 to provide a laser/frequency comb pulse characterized by a desired spectral line spacing (e.g., comb tooth spacing fᵣ). While the illustrated frequency comb generator 400 is configured to use the second harmonic mode, various embodiments may use various harmonic modes. As should be understood, the second harmonic mode has a frequency that is twice the primary mode frequency of the active optical cavity 420.

CPM locking includes generation of two or more pulses within the active optical cavity. For example, in CPM locking, instead of a single pulse circulating within the active optical cavity 420, multiple pulses are generated in the cavity that are spaced evenly along the round-trip path. The two or more pulses are generated such that two or more counter-propagating pulses collide at one or more particular locations within the active optical cavity. In certain embodiments, the one or more particular locations within the active optical cavity are the locations of the SA(s) 450. For example, two or more counter-propagating pulses collide at the SA 450, in an example embodiment. These interactions between the pulses (e.g., colliding at the particular location(s)) enhance pulse shortening and stability of the mode locking, emission spectrum, and/or pulse length of the laser/frequency comb pulses emitted by the frequency comb generator 400.

When CPM locking is performed using harmonic mode locking, multiple pairs of counter-propagating pulses collide within a single round trip. This effectively increases the frequency of pulse collisions and thereby increasing the repetition rate. For example, when the second harmonic is used to perform harmonic mode locking, two pairs of counter-propagating pulses collide per round trip, doubling the effective repetition rate. In other words, increasing the collision events per unit time results in the frequency comb generator having a higher repetition rate.

In some embodiments, the at least a portion of the gain material section 421 is disposed between a first electrode and a second electrode, similar to as shown in FIG. 1A. For example, the first electrode may be formed on the substrate 410, the gain material 425 may be formed at least in part on the first electrode, and the second electrode may be formed on the gain material 425. Application of current or voltage to the first electrode and/or the second electrode causes the gain material 425 to generate photons within the active optical cavity 420. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 410, a through via through the substrate 410, and/or the like. In an example embodiment, the second electrode may be configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 400 may be operated using a current in a range of 50 to 500 mA (e.g., 100-300 mA).

In some embodiments, frequency comb generator 400 may include third and fourth electrodes that are disposed on opposite sides of the SA 450 and configured to be placed in electrical communication with respect current and/or voltage sources (or local ground) and configured to reverse bias the SA 450 (compared to a remainder of the gain material 425 of the gain material section 421). For example, the third electrode may be formed on the substrate 410, the SA 450 may be formed at least in part on the third electrode, and the fourth electrode may be formed on the SA 450. In certain embodiments, the SA 450 may be modulated to provide, for example, active mode locking.

In various embodiments, the gain material section 421 is optically coupled to an output waveguide or waveguide bus 430. For example, optical power (e.g., in the form of a laser/frequency comb pulse 435) that exits the active optical cavity 420 via the second mirror 444 disposed at the second end 438 of the active optical cavity 420, is coupled into the output waveguide or waveguide bus 430. In certain embodiments, the output waveguide or waveguide bus 430 is a silica waveguide or other type of waveguide appropriate for the application.

In various embodiments, the second mirror 444 has a reflectance that is less than 100% such that a portion of the optical power within the active optical cavity 420 may be provided through the second mirror 444 into the output waveguide or waveguide bus 430. The output waveguide or waveguide bus 430 may provide or guide the laser/frequency comb pulse 435 to a downstream element of the system including the frequency comb generator 400.

In some embodiments, the segment adjacent to the output waveguide and/or waveguide bus 430 (e.g., the segment adjacent to the second end 438) includes a waveguide grating. For example, a waveguide grating may be fabricated and/or disposed within a segment of the gain material. For example, the waveguide grating may be configured to filter specific wavelengths such that the specific wavelengths may be used to power the four-wave mixing comb generation process within the gain material section 421.

FIG. 5 illustrates another example frequency comb generator 500 comprising an active optical cavity 520 that uses the second harmonic mode of the active optical cavity 520 to provide a laser/frequency comb pulse characterized by a desired spectral line spacing (e.g., comb tooth spacing fᵣ). The active optical cavity 520 is formed on a substrate 510. In various embodiments, the substrate 510 is a silicon substrate, III-V semiconductor substrate, silica substrate, a silica layer on a silicon substrate, germanium substrate, gallium nitride substrate, and/or another substrate appropriate for the application.

In various embodiments, the active optical cavity 520 includes a gain material section 521. In various embodiments, the gain material section 521 extends along a gain axis 515 from a first end 528 to second end 538. In some embodiments, a first mirror 542, is located and/or disposed at the first end 528 of the active optical cavity 520. In an example embodiment, a first mirror 542 disposed at the first end 528 of the gain material section 521 is configured to be a high reflectivity mirror. For example, the first mirror 542 may be configured to have a reflectivity of greater than 50% and possibly approaching 100% for light in a selected wavelength range or frequency band.

A SA 550 is located and/or disposed at the second end 538 of the active optical cavity 520. For example, the SA 550 may comprise gain material 525 that is biased in an opposite direction from a remainder of the gain material 525 of the gain material section 521.

In various embodiments, the gain material section 521 comprises gain material 525. The gain material may be a III-V semiconductor material such as GaAs; InP; InAs; GaN; InGaAs; or ternary and/or quaternary compounds with Ga, In, As, and/or P, for example, and comprise quantum wells, quantum dashes, quantum dots, and/or the like. In various embodiments, the gain material may be configured to provide laser/frequency comb pulses having one or more spectral lines within the selected wavelength range or frequency band.

In various embodiments, the gain material section 521 is divided into two or more segments. For example, an index gap 560 divides the gain material section 521 into a flared or tapered segment 524 and a non-tapered segment 526. The index gap 560 comprises a gap material that has an index of refraction that is different from the index of refraction of the gain material 525. For example, the index gap 560 may comprise a gap material that has an index of refraction that is lower than the index of refraction of the gain material 525. For example, optical power within the flared or tapered segment 524 may evanescently couple into the non-tapered segment 526 (or vice versa) via the index gap 560.

The flared or tapered segment 524 is a segment of the gain material section 521 where the width of the segment measured in a direction transverse and/or perpendicular to the gain axis 515 and in a plane parallel to a surface plane defined by a surface of the substrate 510, is non-constant along a length of the segment measured in a direction parallel to the gain axis 515. For example, the flared or tapered segment 524 is defined, in part, by a flared or tapered boundary 522 which is not parallel to the gain axis 515. For example, the flared or tapered boundary 522 may form an angle with a line parallel to the gain axis 515 that is greater than 1 degree, in certain embodiments. In some embodiments, the flared or tapered boundary 522 forms an angle with a line parallel to the gain axis 515 that is greater than 3 degrees and less than 90 degrees. The non-tapered segment 526 includes a boundary 527 that is substantially and/or approximately parallel to the gain axis 515. In an example embodiment, the gain material section 521 exhibits a folding symmetry across the gain axis 515.

In various embodiments, the active optical cavity 520 is characterized by a section length C2. The distance from the first end 528 of the gain material section 521 and the second end 538 of the gain material section (along the gain axis 515) is greater than the section length C2. In the illustrated embodiment, the flared or tapered segment 524 has a length (along the gain axis 515) of half the section length C2/2 and the non-tapered segment 526 has a length (along the gain axis 515) of the section length C2. For example, the active optical cavity 520 is configured to generate optical modes in each segment of the gain material section 521 that are characterized by a wavelength equal to the section length C2 and/or harmonics thereof (e.g., C2/2, C2/4, etc.). The optical modes collide at the index gap 560.

The frequency comb generator 500 is configured to use a second harmonic mode of the active optical cavity 520 to provide a laser/frequency comb pulse characterized by a desired spectral line spacing (e.g., comb tooth spacing fᵣ). As should be understood, the second harmonic mode has a wavelength (C2/2) that is half the primary mode wavelength (C2) of the active optical cavity 520 and/or has a frequency that is twice the primary mode frequency of the active optical cavity 520. In certain embodiments, the active optical cavity 520 is configured to cause the second harmonic modes in adjacent segments of the gain material section 521 to collide (e.g., across the interface between the segments provided via the index gap 560) and interfere with one another so as to provide an optical mode characterized by the primary mode frequency/wavelength of the active optical cavity 520.

In some embodiments, the at least a portion of the gain material section 521 is disposed between a first electrode and a second electrode, similar to as shown in FIG. 1A. For example, the first electrode may be formed on the substrate 510, the gain material 525 may be formed at least in part on the first electrode, and the second electrode may be formed on the gain material 525. Application of current or voltage to the first electrode and/or the second electrode causes the gain material 525 to generate photons within the active optical cavity 520. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 510, a through via through the substrate 510, and/or the like. In an example embodiment, the second electrode may be configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 500 may be operated using a current in a range of 50 to 500 mA (e.g., 100-300 mA).

In some embodiments, frequency comb generator 500 may include third and fourth electrodes that are disposed on opposite sides of the SA 550 and configured to be placed in electrical communication with respect current and/or voltage sources (or local ground) and configured to reverse bias the SA 550 (compared to a remainder of the gain material 525 of the gain material section 521). For example, the third electrode may be formed on the substrate 510, the SA 550 may be formed at least in part on the third electrode, and the fourth electrode may be formed on the SA 550.

In various embodiments, the gain material section 521 is optically coupled to an output waveguide or waveguide bus 530. For example, optical power (e.g., in the form of a laser/frequency comb pulse) that exits the active optical cavity 520 via the SA 550 disposed at the second end 538 of the active optical cavity 520, is coupled into the output waveguide or waveguide bus 530. In certain embodiments, the output waveguide or waveguide bus 530 is a silica waveguide or other type of waveguide appropriate for the application. The output waveguide or waveguide bus 530 may provide or guide the laser/frequency comb pulse to a downstream element of the system including the frequency comb generator 500.

FIGS. 6, 7, and 8 illustrate some example frequency comb generators 600, 700, 800 that comprise respective active optical cavities 620, 720, 820 that use the fourth harmonic mode of the active optical cavity 620, 720, 820 to provide a laser/frequency comb pulse characterized by a desired spectral line spacing (e.g., comb tooth spacing fᵣ). The active optical cavities 620, 720, 820 is formed on respective substrates 610, 710, 810. In various embodiments, the substrate 610, 710, 810 is a silicon substrate, III-V semiconductor substrate, silica substrate, a silica layer on a silicon substrate, germanium substrate, gallium nitride substrate, and/or another substrate appropriate for the application.

In various embodiments, the active optical cavities 620, 720, 820 include respective gain material sections 621, 721, 821. In various embodiments, the gain material section 621, 721, 821 extends along a gain axis 615, 715, 815 from a first end 628, 728, 828 to second end 638, 738, 838. In some embodiments, a first mirror 642, 742, 842 is located and/or disposed at the first end 628, 728, 828 of the active optical cavity 620, 720, 820. In an example embodiment, a first mirror 642, 742, 842 disposed at the first end 628, 728, 828 of the gain material section 621, 721, 821 is configured to be a high reflectivity mirror. For example, the first mirror 642, 742, 842 may be configured to have a reflectivity of greater than 50% and possibly approaching 100% for light in a selected wavelength range or frequency band. In some embodiments, a second mirror 644, 744, 844 is disposed at the second end 638, 738, 838 of the gain material section 621, 721, 821. In various embodiments, the second mirror 644, 744, 844 has a reflectance that is less than 100% such that a portion of the optical power within the active optical cavity 620, 720, 820 may be provided through the second mirror 644, 744, 844 into an output waveguide or waveguide bus 630, 730, 830. Some embodiments may include an SA located and/or disposed at the second end 638, 738, 838 of the active optical cavity 620, 720, 820 instead of the second mirror 644, 744, 844.

In various embodiments, the gain material section 621, 721, 821 comprises gain material 625, 725, 825. The gain material may be a III-V semiconductor material such as GaAs; InP; InAs; GaN; InGaAs; or ternary and/or quaternary compounds with Ga, In, As, and/or P, for example, and comprise quantum wells, quantum dashes, quantum dots, and/or the like. In various embodiments, the gain material may be configured to provide laser/frequency comb pulses having one or more spectral lines within the selected wavelength range or frequency band.

In various embodiments, the gain material section 621, 721, 821 is divided into two or more segments. For example, a first SA 650A, 750A, 850A and a second SA 650B, 750B, 750B may divide the gain material section 621, 721, 821 into three segments. In some embodiments, one or more index gaps may be used divide the gain material into two or more segments. In some embodiments, a combination of one or more index gaps and one or more SAs may be used to divide the gain material section 621, 721, 821 into a plurality of segments.

The frequency comb generator 600 includes a flared or tapered segment 624 located adjacent to the first end 628 of the gain material section 621, a first non-tapered segment 626A located between the first SA 650A and the second SA 650B, and a second non-tapered segment 626B located adjacent the second end 638 of the gain material section 621. The flared or tapered segment 624 is a segment of the gain material section 621 where the width of the segment measured in a direction transverse and/or perpendicular to the gain axis 615 and in a plane parallel to a surface plane defined by a surface of the substrate 610, is non-constant along a length of the segment measured in a direction parallel to the gain axis 615. For example, the flared or tapered segment 624 is defined, in part, by a flared or tapered boundary 622 which is not parallel to the gain axis 615. For example, the flared or tapered boundary 622 may form an angle with a line parallel to the gain axis 615 that is greater than 1 degree, in certain embodiments. In some embodiments, the flared or tapered boundary 622 forms an angle with a line parallel to the gain axis 615 that is greater than 3 degrees and less than 90 degrees. The non-tapered segments 626A, 626B each include boundaries that are substantially and/or approximately parallel to the gain axis 615. For example, the widths of the non-tapered segments 626A, 626B measured in a direction transverse and/or perpendicular to the gain axis 615 and in a plane parallel to a surface plane defined by a surface of the substrate 610, is constant or uniform along a length of the segment measured in a direction parallel to the gain axis 615. In an example embodiment, the gain material section 621 exhibits a folding symmetry across the gain axis 615.

In various embodiments, the active optical cavity 620 is characterized by a section length C3. The distance from the first end 628 of the gain material section 621 and the second end 638 of the gain material section (along the gain axis 615) is greater than the section length C3. In the illustrated embodiment, the flared or tapered segment 624 has a length (along the gain axis 615) of half the section length C3/2, the first non-tapered segment 626A has a length (along the gain axis 615) of the section length C3, and the second non-tapered segment 626B has a length (along the gain axis 615) of half the section length C3/2. For example, the active optical cavity 620 is configured to generate optical modes in each segment of the gain material section 621 that are characterized by a wavelength equal to the section length C3 and/or harmonics thereof (e.g., C3/2, C3/4, etc.). The optical modes collide at SAs 650A, 650B.

The frequency comb generator 700 includes a first flared or tapered segment 724A located adjacent to the first end 728 of the gain material section 721, a second flared or tapered segment 724B located between the first SA 750A and the second SA 750B, and a non-tapered segment 726 located adjacent the second end 738 of the gain material section 721. The first and second flared or tapered segments 724A, 724B are a segments of the gain material section 721 where the width of the segment measured in a direction transverse and/or perpendicular to the gain axis 715 and in a plane parallel to a surface plane defined by a surface of the substrate 710, is non-constant along a length of the segment measured in a direction parallel to the gain axis 715. For example, the first flared or tapered segment 724A is defined, in part, by a flared or tapered boundary 722 which is not parallel to the gain axis 715. For example, the flared or tapered boundary 722 may form an angle Y with a line parallel to the gain axis 715 that is greater than 1 degree, in certain embodiments. In some embodiments, the flared or tapered boundary 722 forms an angle Y with a line parallel to the gain axis 715 that is greater than 3 degrees and less than 90 degrees. The non-tapered segment 726 includes boundaries that are substantially and/or approximately parallel to the gain axis 715. For example, the width of the non-tapered segment 726 measured in a direction transverse and/or perpendicular to the gain axis 715 and in a plane parallel to a surface plane defined by a surface of the substrate 710, is constant or uniform along a length of the segment measured in a direction parallel to the gain axis 715. In an example embodiment, the gain material section 721 exhibits a folding symmetry across the gain axis 715. In some embodiments, the angle formed between a flared or tapered boundary with a line parallel to the gain axis 715 is the same for each flared or tapered segment 724. In certain embodiments, the angle formed between a flared or tapered boundary with a line parallel to the gain axis 715 is different for different flared or tapered segments 724.

In various embodiments, the active optical cavity 720 is characterized by a section length C4. The distance from the first end 728 of the gain material section 721 and the second end 738 of the gain material section (along the gain axis 715) is greater than the section length C4. In the illustrated embodiment, the first flared or tapered segment 724 has a length (along the gain axis 715) of half the section length C4/2, the second flared or tapered segment 724B has a length (along the gain axis 715) of the section length C4, and the non-tapered segment 726 has a length (along the gain axis 715) of half the section length C4/2. For example, the active optical cavity 720 is configured to generate optical modes in each segment of the gain material section 721 that are characterized by a wavelength equal to the section length C4 and/or harmonics thereof (e.g., C4/2, C4/4, etc.). The optical modes collide at SAs 750A, 750B.

The frequency comb generator 800 includes a first flared or tapered segment 824A located adjacent to the first end 828 of the gain material section 721, a second flared or tapered segment 824B located between the first SA 850A and the second SA 850B, and a third flared or tapered segment 826C located adjacent the second end 838 of the gain material section 821. The first, second, and third flared or tapered segments 824A, 824B, 824C are a segments of the gain material section 821 where the width of the segment measured in a direction transverse and/or perpendicular to the gain axis 815 and in a plane parallel to a surface plane defined by a surface of the substrate 810, is non-constant along a length of the segment measured in a direction parallel to the gain axis 815. For example, the first flared or tapered segment 824A is defined, in part, by a flared or tapered boundary 822 which is not parallel to the gain axis 815. For example, the flared or tapered boundary 822 may form an angle with a line parallel to the gain axis 815 that is greater than 1 degree, in certain embodiments. In some embodiments, the flared or tapered boundary 822 forms an angle with a line parallel to the gain axis 815 that is greater than 3 degrees and less than 90 degrees. In an example embodiment, the gain material section 821 exhibits a folding symmetry across the gain axis 815. In some embodiments, the angle formed between a flared or tapered boundary with a line parallel to the gain axis 815 is the same for each flared or tapered segment 824. In certain embodiments, the angle formed between a flared or tapered boundary with a line parallel to the gain axis 815 is different for different flared or tapered segments 824.

In various embodiments, the active optical cavity 820 is characterized by a section length C5. The distance from the first end 828 of the gain material section 821 and the second end 838 of the gain material section (along the gain axis 815) is greater than the section length C5. In the illustrated embodiment, the first flared or tapered segment 824 has a length (along the gain axis 815) of half the section length C5/2, the second flared or tapered segment 524B has a length (along the gain axis 515) of the section length C5, and the non-tapered segment 826 has a length (along the gain axis 815) of half the section length C5/2. For example, the active optical cavity 820 is configured to generate optical modes in each segment of the gain material section 821 that are characterized by a wavelength equal to the section length C5 and/or harmonics thereof (e.g., C5/2, C5/4, etc.). The optical modes collide at SAs 850A, 850B.

The frequency comb generators 600, 700, 800 are configured to use a fourth harmonic mode of the active optical cavities 620, 720, 820 to provide a laser/frequency comb pulse characterized by a desired spectral line spacing (e.g., comb tooth spacing fᵣ). As should be understood, the fourth harmonic mode has a wavelength (C3/4, C4/4, C5/4) that is one quarter of the primary mode wavelength (C3, C4, C5) of the respective active optical cavity 620, 720, 820 and/or has a frequency that is four times the primary mode frequency of the respective active optical cavity 620, 720, 820. In certain embodiments, the active optical cavities 620, 720, 820 is configured to cause the fourth harmonic modes in adjacent segments of the gain material section 621, 721, 821 to collide (e.g., across the interface between the segments provided via the SAs 650A, 650B, 750A, 750B, 850A, 850B) and interfere with one another so as to provide an optical mode characterized by the primary mode frequency/wavelength of the respective active optical cavity 620, 720, 820.

In some embodiments, the at least a portion of the gain material section 621, 721, 821 is disposed between a first electrode and a second electrode, similar to as shown in FIG. 1A. For example, the first electrode may be formed on the substrate 610, 710, 810, the gain material 625, 725, 825 may be formed at least in part on the first electrode, and the second electrode may be formed on the gain material 625, 725, 825. Application of current or voltage to the first electrode and/or the second electrode causes the gain material 625, 725, 825 to generate photons within the active optical cavity 620, 720, 820. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 610, 710, 810, a through via through the substrate 610, 710, 810, and/or the like. In an example embodiment, the second electrode may be configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 600, 700, 800 may be operated using a current in a range of 50 to 500 mA (e.g., 100-300 mA).

In some embodiments, frequency comb generator 600, 700, 800 may include one or more pairs of third and fourth electrodes that are disposed on opposite sides of a respective SA 650A, 650B, 750A, 750B, 850A, 850B and configured to be placed in electrical communication with respect current and/or voltage sources (or local ground) and configured to reverse bias the SA 650A, 650B, 750A, 750B, 850A, 850B (compared to a remainder of the gain material 625, 725, 825 of the gain material section 621, 721, 821). For example, the third electrode of a respective pair of third and fourth electrodes may be formed on the substrate 610, 710, 810, a respective SA 650A, 650B, 750A, 750B, 850A, 850B may be formed at least in part on the third electrode, and the fourth electrode of the respective pair of third and fourth electrodes may be formed on the respective SA 650A, 650B, 750A, 750B, 850A, 850B.

In various embodiments, the gain material section 621, 721, 821 is optically coupled to an output waveguide or waveguide bus 630, 730, 830. For example, optical power (e.g., in the form of a laser/frequency comb pulse) that exits the active optical cavity 620, 720, 820 via the second mirror 644, 744, 844 disposed at the second end 638, 738, 838 of the active optical cavity 620, 720, 820 is coupled into the output waveguide or waveguide bus 630, 730, 830. In certain embodiments, the output waveguide or waveguide bus 630, 730, 830 is a silica waveguide or other type of waveguide appropriate for the application. The output waveguide or waveguide bus 630, 730, 830 may provide or guide the laser/frequency comb pulse to a downstream element of the system including the frequency comb generator 600, 700, 800. The output waveguide or waveguide bus 630, 730, 830 may provide or guide the laser/frequency comb pulse to a downstream element of the system including the frequency comb generator 600, 700, 800.

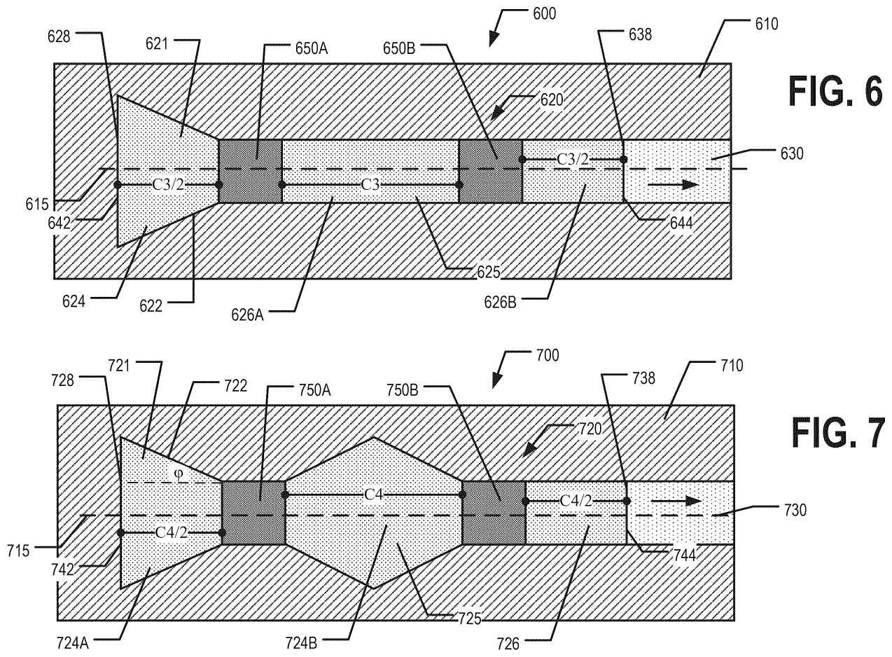

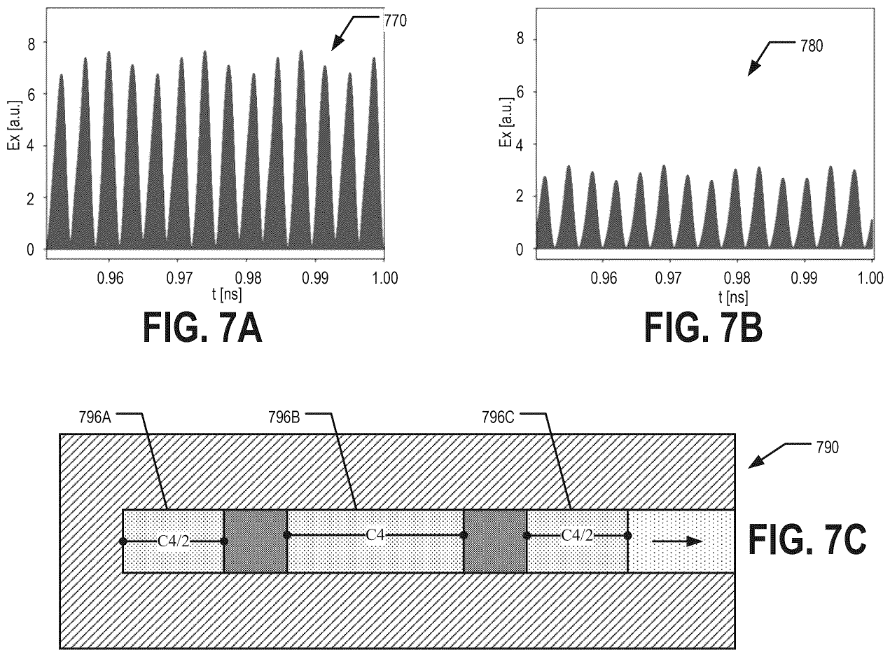

FIG. 7A provides a plot 770 showing simulation results of the extracted power (in arbitrary units a.u.) with respect to time of the frequency comb generator 700, in an example embodiment where the length of the active optical cavity 720 (e.g., gain section between the first end 728 and the second end 738 along the gain axis 715) is 200 microns, the length of the SAs 750A, 750B (along the gain axis 715) are both 30 microns, and the angle φ formed between the tapered boundary 722 with a line parallel to the gain axis 715 that is 5 degrees. The simulation corresponds to driving the frequency comb generator 700 with a current of 200 mA. In other words, the simulation corresponds to a current of 200 mA being applied to one of the first electrode or the second electrode.

FIG. 7B provides a plot 780 showing simulation results of the extracted power (in arbitrary units a.u.) with respect to time of the frequency comb generator 790 shown in FIG. 7C. The frequency comb generator 790 is similar to the frequency comb generator 700 with the flared or tapered segments 724A, 724B replaced with non-tapered sections. For example, the frequency comb generator 790 includes three non-tapered sections 796A, 796B, 796C. The simulation results shown in FIG. 7B correspond to driving the frequency comb generator 790 with a current of 450 mA.

As can be seen by comparing FIGS. 7A and 7B, the frequency comb generator 700 provides significantly more optical power (e.g., in the form of laser/frequency comb pulses) compared to the frequency comb generator 790 while having a significantly smaller current applied thereto.

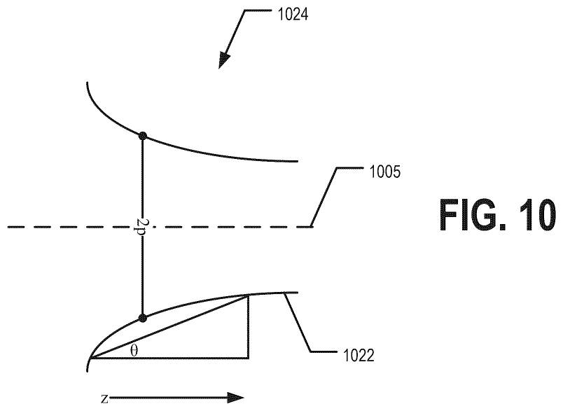

FIG. 9 illustrates an example frequency comb generator 900 that comprises an active optical cavity 920 that uses the sixth harmonic mode of the active optical cavity 920 to provide a laser/frequency comb pulse characterized by a desired spectral line spacing (e.g., comb tooth spacing fᵣ). The active optical cavity 920 is formed on a substrate 910. In various embodiments, the substrate 910 is a silicon substrate, III-V semiconductor substrate, silica substrate, a silica layer on a silicon substrate, germanium substrate, gallium nitride substrate, and/or another substrate appropriate for the application.

In various embodiments, the active optical cavity 920 includes a gain material section 921. In various embodiments, the gain material section 921 extends along a gain axis 915 from a first end 928 to second end 938. In some embodiments, a first mirror 942 is located and/or disposed at the first end 928 of the active optical cavity 920. In an example embodiment, a first mirror 942 disposed at the first end 928 of the gain material section 921 is configured to be a high reflectivity mirror. For example, the first mirror 942 may be configured to have a reflectivity of greater than 50% and possibly approaching 100% for light in a selected wavelength range or frequency band. In some embodiments, a second mirror 944 is disposed at the second end 938 of the gain material section 921. In various embodiments, the second mirror 944 has a reflectance that is less than 100% such that a portion of the optical power within the active optical cavity 920 may be provided through the second mirror 944 into an output waveguide or waveguide bus 930. Some embodiments may include an SA located and/or disposed at the second end 938 of the active optical cavity 920 instead of the second mirror 944.

In various embodiments, the gain material section 921 comprises gain material 925. The gain material may be a III-V semiconductor material such as GaAs; InP; InAs; GaN; InGaAs; or ternary and/or quaternary compounds with Ga, In, As, and/or P, for example, and comprise quantum wells, quantum dashes, quantum dots, and/or the like. In various embodiments, the gain material may be configured to provide laser/frequency comb pulses having one or more spectral lines within the selected wavelength range or frequency band.

In various embodiments, the gain material section 921 is divided into two or more segments via dividers (e.g., SAs, index gaps, and/or the like). For example, a first SA 950A, a second SA 950B, and a third SA 950C may divide the gain material section 921 into three segments. In some embodiments, one or more index gaps may be used divide the gain material into two or more segments. In some embodiments, a combination of one or more index gaps and one or more SAs may be used to divide the gain material section 921 into a plurality of segments.

The frequency comb generator 900 includes a flared or tapered segment 924 located adjacent to the first end 928 of the gain material section 921, a first non-tapered segment 926A located between the first SA 950A and the second SA 950B, a second non-tapered segment 926B located between the second SA 950B and the third SA 950C, and a third non-tapered segment 926C adjacent the second end 938 of the gain material section 921.

The flared or tapered segment 924 is a segment of the gain material section 921 where the width of the segment measured in a direction transverse and/or perpendicular to the gain axis 915 and in a plane parallel to a surface plane defined by a surface of the substrate 910, is non-constant along a length of the segment measured in a direction parallel to the gain axis 915. For example, the flared or tapered segment 924 is defined, in part, by a flared or tapered boundary 922 which is not parallel to the gain axis 915. For example, the flared or tapered boundary 922 may form an angle with a line parallel to the gain axis 915 that is greater than 1 degree, in certain embodiments. In some embodiments, the flared or tapered boundary 922 forms an angle with a line parallel to the gain axis 915 that is greater than 3 degrees and less than 90 degrees.

The non-tapered segments 926A, 926B, 926C each include boundaries that are substantially and/or approximately parallel to the gain axis 915. For example, the widths of the non-tapered segments 926A, 926B, 926C measured in a direction transverse and/or perpendicular to the gain axis 915 and in a plane parallel to a surface plane defined by a surface of the substrate 910, is constant or uniform along a length of the segment measured in a direction parallel to the gain axis 915. In an example embodiment, the gain material section 921 exhibits a folding symmetry across the gain axis 915.

In various embodiments, the active optical cavity 920 is characterized by a section length C6. The distance from the first end 928 of the gain material section 921 and the second end 938 of the gain material section (along the gain axis 915) is greater than the section length C6. In the illustrated embodiment, the flared or tapered segment 924 has a length (along the gain axis 915) of half the section length C6/2, the first non-tapered segment 926A has a length (along the gain axis 915) of the section length C6, the second non-tapered segment 928B has a length (along the gain axis 915) of the section length C6, and the third non-tapered segment 926C has a length (along the gain axis 915) of half the section length C6/2. For example, the active optical cavity 920 is configured to generate optical modes in each segment of the gain material section 921 that are characterized by a wavelength equal to the section length C6 and/or harmonics thereof (e.g., C6/2, C6/4, etc.). The optical modes collide at SAs 950A, 950B, 950C.

The frequency comb generator 900 is configured to use a sixth harmonic mode of the active optical cavity 920 to provide a laser/frequency comb pulse characterized by a desired spectral line spacing (e.g., comb tooth spacing fᵣ). As should be understood, the sixth harmonic mode has a wavelength (C6/6) that is one quarter of the primary mode wavelength (C6) of the active optical cavity 920 and/or has a frequency that is six times the primary mode frequency of the active optical cavity 920. In certain embodiments, the active optical cavity 920 is configured to cause the sixth harmonic modes in adjacent segments of the gain material section 921 to collide (e.g., across the interface between the segments provided via the SAs 950A, 950B, 950C) and interfere with one another so as to provide an optical mode characterized by the primary mode frequency/wavelength of the active optical cavity 920. Various embodiments provide other frequency comb generators configured to use a sixth harmonic mode of the active optical cavity to provide a laser/frequency comb pulse characterized by a desired spectral line spacing (e.g., comb tooth spacing fᵣ) where one or more of the non-tapered segments 926A, 926B, 926C are replaced by flared or tapered segments of the same length along the gain axis 915.

In some embodiments, the at least a portion of the gain material section 921 is disposed between a first electrode and a second electrode, similar to as shown in FIG. 1A. For example, the first electrode may be formed on the substrate 910, the gain material 925 may be formed at least in part on the first electrode, and the second electrode may be formed on the gain material 925. Application of current or voltage to the first electrode and/or the second electrode causes the gain material 925 to generate photons within the active optical cavity 920. In various embodiments, the first electrode and the second electrode comprise a conductive material such as a metal or another appropriate material. In an example embodiment, the first electrode is configured to be placed into electrical communication with an electrical current or voltage source (or local ground) via a lead formed on or in the substrate 910, a through via through the substrate 910, and/or the like. In an example embodiment, the second electrode may be configured to be placed into electrical communication with an electrical current or voltage source (or local ground) via one or more electrode pads, leads, and/or the like formed on and/or in electrical communication with an exposed surface of the second electrode. In an example embodiment, the frequency comb generator 900 may be operated using a current in a range of 50 to 500 mA (e.g., 100-300 mA).

In some embodiments, frequency comb generator 600, 700, 800 may include one or more pairs of third and fourth electrodes that are disposed on opposite sides of a respective SA 950A, 950B, 950C and configured to be placed in electrical communication with respect current and/or voltage sources (or local ground) and configured to reverse bias the SA 950A, 950B, 950C (compared to a remainder of the gain material 925 of the gain material section 921). For example, the third electrode of a respective pair of third and fourth electrodes may be formed on the substrate 910, a respective SA 950A, 950B, 950C may be formed at least in part on the third electrode, and the fourth electrode of the respective pair of third and fourth electrodes may be formed on the respective SA 950A, 950B, 950C.

In various embodiments, the gain material section 921 is optically coupled to an output waveguide or waveguide bus. For example, optical power (e.g., in the form of a laser/frequency comb pulse) that exits the active optical cavity 920 via the second mirror 944 (or other confinement element) disposed at the second end 938 of the active optical cavity 920 is coupled into the output waveguide or waveguide bus 930. In certain embodiments, the output waveguide or waveguide bus 930 is a silica waveguide or other type of waveguide appropriate for the application. The output waveguide or waveguide bus 930 may provide or guide the laser/frequency comb pulse to a downstream element of the system including the frequency comb generator 900. The output waveguide or waveguide bus 930 may provide or guide the laser/frequency comb pulse to a downstream element of the system including the frequency comb generator 900.

In various embodiments, a frequency comb generator may be configured to use higher order harmonics (e.g., an eight harmonic mode, tenth harmonic mode, and/or the like) of the active optical cavity 920 to provide a laser/frequency comb pulse characterized by a desired spectral line spacing (e.g., comb tooth spacing fᵣ). The gain material section of the active optical cavity may be divided into a two or more segments with each segment having an optical length (e.g., an optical travel length from one divider to the next divider) that is an integer multiplied by the section length of the active optical cavity. For example, for the frequency comb generator 900, the flared or tapered segment 924 has a physical length along the gain axis of C6/2, where C6 is the section length of the active optical cavity 920. The optical length of the flared or tapered segment 924 is measured from the first SA 950A to the first end 928 (e.g., first mirror 942) and then back to the first SA 950A. So the optical length of the flared or tapered segment 924 is C6. The optical length of the first non-tapered segment 926A is measured from the first SA 950A to the second SA 950B (or vice versa). So the optical length of the first non-tapered segment 926A is C6. Various combinations of dividers and confinement elements may be used in various embodiments.

In some embodiments, the flared or tapered boundaries 422, 522, 622, 722, 822, 922 are straight tapers. A straight taper is a straight line. For example, the derivative of a flared or tapered boundary that is a straight taper with respect to position along the gain axis is constant.

In some embodiments, the flared or tapered boundaries 422, 522, 622, 722, 822, 922 are adiabatic tapers, as shown in FIG. 10. FIG. 10 illustrates an example of at least a portion of a flared or tapered segment 1024 that extends along a gain axis 1005 and is defined at least in part by the flared or tapered boundary 1022, which is an adiabatic taper. An adiabatic taper satisfies

$$\frac{dp}{dz} \leq \frac{p \vert {β}_{1} - {β}_{2} \vert}{2 π} ,$$

where dp/dz is the rate of change of the waveguide half-width p with respect to propagation direction z, p is the local half-width of the segment, β₁ is the propagation constant of the fundamental or primary mode, β₂ is the propagation constant of the next higher order mode, and z is the propagation direction. As illustrated in FIG. 10,

$$θ = arctan ( \frac{dp}{dz} ) .$$

Thus, the adiabatic taper satisfies

$$θ \leq arctan ( \frac{p \vert {β}_{1} - {β}_{2} \vert}{2 π} ) ,$$

where the angle θ is in radians.

In various embodiments, additional optical components may be positioned between the second end of the active optical cavity and the output waveguide or waveguide bus. In some embodiments, the output waveguide or waveguide bus may be coupled to additional optical components. In certain embodiments, the additional optical components may include waveguide polarization splitters, rotators, combiners, and/or the like for use with a polarization multiplexing scheme. The optical ring resonator can be operated as both a demultiplexer and a modulator. Electronics can encode data onto an optical channel. Such a method of operating the device results in an encoded optical channel being output on the output waveguide.

The optical device may include one or more waveguides that carry light signals to and/or from optical components. Examples of optical components that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device from the bottom side of the device to the top side of the device. Additionally, the device can include electrical components. For instance, the device can include electrical connections for applying a potential or current to a waveguide and/or for controlling other components on the optical device.

### Example System Including a Frequency Comb Generator

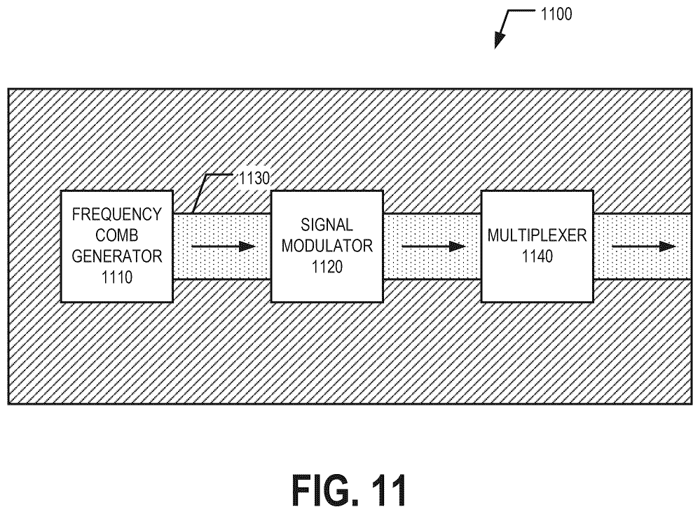

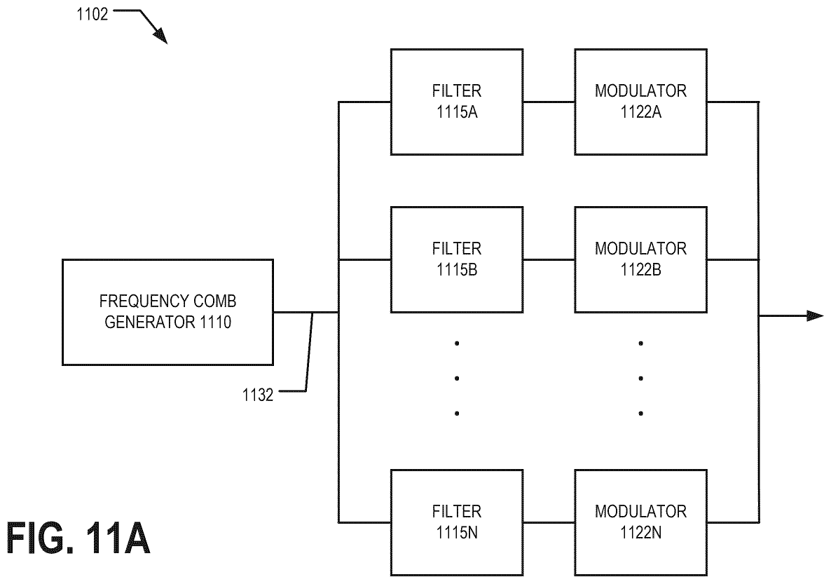

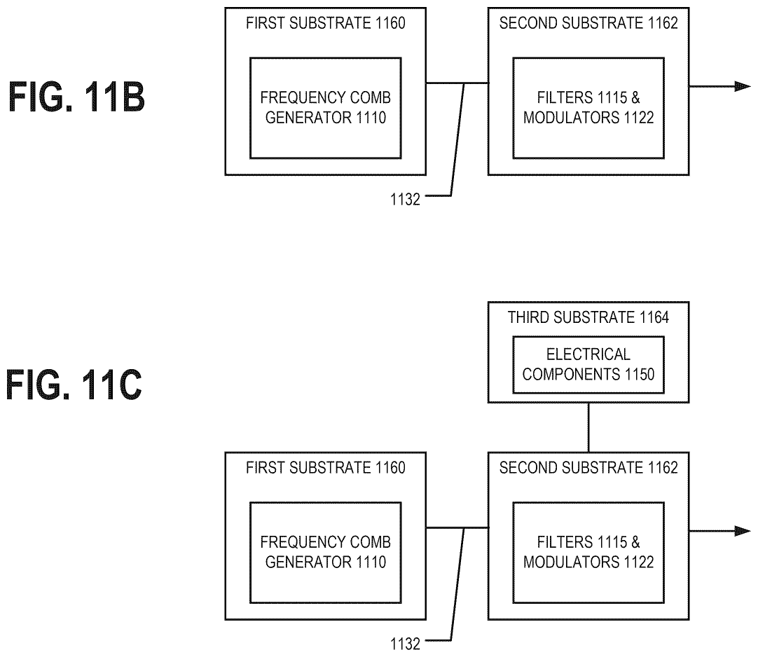

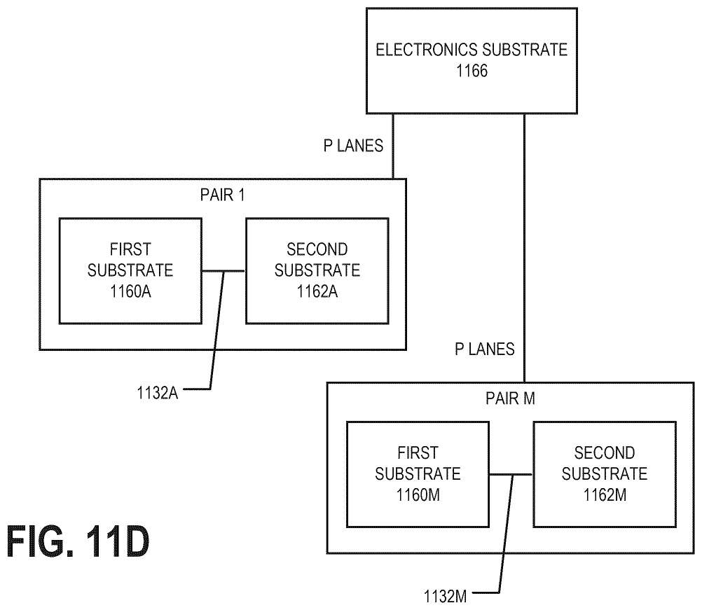

FIG. 11 illustrates an example system 1100 including a frequency comb generator 1110. For example, a frequency comb generator 1110 may be a frequency comb generator having closed loop or ring of gain material disposed within the active optical cavity and/or having a gain material section divided into a plurality (e.g., two or more) segments with at least one of the segments being a flared or tapered segment. The output waveguide or waveguide bus 1130 guides and/or provides laser/frequency comb pulses generated and provide by the frequency comb generator 1110 to one or more downstream elements of the system 1100 that use the laser/frequency comb pulses to perform various tasks, optical communications, and/or the like.

For example, the output waveguide or waveguide bus 1130 may guide and/or provide the laser/frequency comb pulses to a signal modulator 1120. In certain embodiments, the signal modulator 1120 is configured to modulate one or more spectral lines of sequence or train of laser/frequency comb pulses so as to encode information therein/thereon. A waveguide, optical fiber, and/or the like may provide the laser/frequency comb pulses having the one or more modulated spectral lines to a multiplexer 1140 that may be used to multiplex the one or more modulated spectral lines. The laser/frequency comb pulses may then be transmitted along a waveguide, optical fiber, and/or the like to communicate the information encoded therein/thereon with one or more downstream elements (e.g., an optical receiver and/or the like).

In various embodiments, the system 1100 is or includes a high-speed transceiver. In some embodiments, the system 1100 is or is part of a multi-chip module (MCM). In some embodiments, the frequency comb generator 1110 is formed on the same substrate or die as other components of the transceiver (e.g., signal modulator 1120, multiplexer 1140, and/or the like). In certain embodiments, the frequency comb generator 1110 is formed on a first substrate or die and the transceiver is formed on a second substrate or die and the frequency comb generator 1110 is in optical communication with the transceiver via an optical interconnect (e.g., optical fiber, polymer flex waveguide, and/or the like optically coupled to output waveguide or waveguide bus 1130). For example, in some embodiments, the downstream elements of the system 1100 (e.g., to which laser/frequency comb pulses generated by the frequency comb generator 1110 are provided via the output waveguide or waveguide bus 1130) one or more optical interconnects and one or more transceivers.

There are different techniques of implementation to modulate the light coming out of the frequency comb generator 1110. In an example embodiment, the frequency comb generator 1110 provides laser/frequency comb pulses including a plurality of equidistantly spaced (in wavelength space) spectral lines, then the different wavelengths are filtered by dedicated filters. Each filter has a central wavelength designed to match one of the spectral lines of the plurality of spectral lines at that wavelength only. The signal from that filter, which is a narrow wavelength band (sometimes called a single wavelength, even though it has a bandwidth), is then sent to an optical modulator, for example, a Mach-Zehnder modulator, which modulates the optical signal by an electrical signal. The electrical signal may be a non-return to zero (NRZ) modulator, a four-level pulse amplitude modulator (PAM-4), or a modulator applying any multi-level signal conveying device technique, for example, like coding digital information into any format.

FIG. 11A illustrates an example system 1102 where a frequency comb generator 1110 is incorporated into an N-channel system with each filter including a respective filter 1115A, 1115B, . . . , 1115N. For example, the system 1102 implements a filtering technique where a dedicated filter 1115A, 1115B, . . . , 1115N is employed for each spectral line responding to one wavelength band. This dedicated filter extracts the wavelength band and sends the respective single spectral line to a respective modulator 1122A, 1122B, . . . , 1122BN, and the respective modulator performs phase modulation or amplitude modulation according to applications. The modulator can be a Mach-Zehnder modulator, a micro-ring modulator, and/or the like. For example, the frequency comb generator 1110 provides laser/frequency comb pulses which are provided, via optical interconnect 1132 (e.g., optical fiber, polymer flex waveguide(s), and/or another waveguide(s)) to a number of filters 1115A, 1115B, . . . , 1115N that are used to separate the lines of the frequency comb, and a number of modulators 1122A, 1122B, . . . , 1122N, each following one of the filters, are used to independently modulate that spectral line. For example, the system 1102 includes N channels and the frequency comb generator is in optical communication with N channels, and each channel is formed of one filter and one modulator connected in series. The outputs of the N channels are combined into optical fiber cables to provide a single output comprising a plurality of individually modulated spectral lines.

FIGS. 11B-11D show schematic diagrams of three example systems including frequency comb generators 1110 implemented in multi-chip modules (MCM), which include a first substrate or die housing the frequency comb generator and a second substrate or die housing the filtering and modulation components (e.g., filters 1115A, . . . , 1115N and modulators 1122A, . . . , 1122N). In some of the illustrated embodiments, the system includes a third substrate or die housing electronic components of the system.

In FIG. 11B, there are two substrates or dies—a first substrate or die 1160 housing the frequency comb generator 1110 and a second substrate or die 1162 housing photonic components such as the filters 1115 and modulators 1122. For example, the second substrate or die 1162 a silicon photonics chip housing a photonic integrated circuit. The first substrate or die 1160 and the second substrate or die 1162 are interconnected through an optical conduit or interconnect 1132 made of an optical fiber, a polymer waveguide, a glass waveguide, or other interconnecting lines. In various embodiments, the second substrate or die 1162 includes filtering and modulation blocks to select and modulate each separate spectral line of the laser/frequency comb pulses provided by the frequency comb generator 1110.

In FIG. 11C, the system in FIG. 11B is extended with a third substrate or die 1164, which is an electronics die containing all the systems for electronic manipulation of signals, including but not limited to equalization, coding, switching, and logic operations.

In FIG. 11D, the multichip module (MCM) implementation is further extended. A central electronics substrate or die 1166 containing all signal manipulation electronics is surrounded by M pairs of photonics substrates or dies. Each pair of photonics substrates or dies includes a first substrate or die 1160A, . . . , 1160M housing a respective frequency comb generator 1110 and a second substrate or die 1162A, . . . , 1162M of silicon photonics for frequency combing (e.g., filtering, modulating of individual spectral lines, and combining the plurality (e.g., N) of individually modulated spectral lines). Each pair of first substrate or die 1160 and second substrate or die 1162 are interconnected by a respective optical interconnect 1132A, . . . , 1132M such as a conduit of optical fibers, a polymer waveguide, or a glass waveguide, similar to the system described in FIG. 11B. The central electronics substrate or die 1166 is connected to each of the photonics pair of first substrate or die 1160 and second substrate or die 1162 through P lanes of electrical connections. The P planes of electrical connections may include power lanes, low frequency lanes, and/or high frequency lanes.

The integration of frequency comb generators into transceivers also offers the opportunity to extend a transceiver from a wavelength WDM source, for example, a four-wavelength channel scheme, to coarse-WDM (CWDM) as in eight wavelength channels. The similar frequency comb generators can be used to generate either four wavelengths to feed a WDM link or eight wavelengths to feed a CWDM link. In some embodiments, integration of frequency comb generators into transceivers further enables extension to dense WDM (DWDM).

For example, in certain embodiments a multi-chip module (MCM) has M photonics frequency comb generators 1110, each comprising a pair of the first substrate and a second substrate. In some examples, the MCM further comprises an electronics substrate connecting to the M photonics frequency comb generators, respectively, via a multi-lane electrical connection, wherein the electronics substrate or die 1166 comprises circuits for electronic manipulation of signals, including equalization, coding, switching, and logic operations.

### Example Datacenter

In various embodiments, a system including a frequency comb generator (e.g., system 1100) may be part of a datacenter. For example, system may be part of a transceiver, interconnect and/or the like used to place various components of a datacenter in communication with one another. In various embodiments, the system 1100 may be a pluggable optical interconnect that uses a frequency comb generator of an example embodiment as a laser source, a chip-to-chip optical interconnect that uses a frequency comb generator of an example embodiment as a laser source, a DWDM source, and/or the like. For example, a system 1100 may be used to (optically) transmit data between components of a datacenter, in various embodiments. For example, a frequency comb generator 100, 200, 300, 400, 500, 600, 700, 800, 900 may be used to generate optical signals that are transmitted along one or more optical communication paths between two components of a datacenter, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gb/s. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

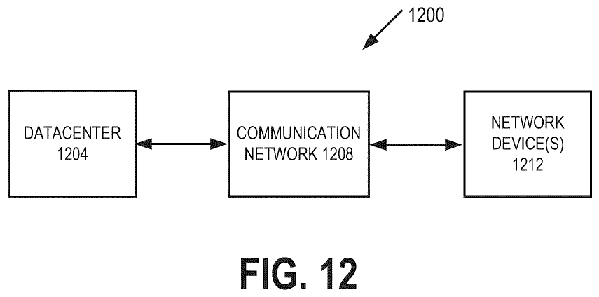

FIG. 12 illustrates a system 1200 according to at least one example embodiment. The system 1200 includes a datacenter 1204, a communication network 1208, and one or more network devices 1212. In at least one example embodiment, the datacenter 1204 corresponds to a collection of network devices, such as network switches (e.g., Ethernet switches) connected with a collection of servers or compute nodes. The datacenter 1204 may adhere to a networking topology (e.g., a hierarchal networking topology), such as a fat tree topology, a Slim Fly topology, a Dragonfly topology, and/or the like. The datacenter 1204 routes traffic amongst the network switches and servers therein, and at least one layer of the topology in the datacenter 1204 is coupled to the communication network 1208 to allow networking traffic to flow between the datacenter 1204 and the network device(s) 1212.

Examples of the communication network 1208 that may be used to connect the datacenter 1204 and the network device(s) 1212 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 1212 may include one or more of Personal Computer (PC), a laptop, a tablet, a smartphone, a server, a collection of servers, and/or any suitable computing device for sending and receiving signals over the communication network 1208. In at least one example embodiment, the one or more network devices 1212 correspond to another datacenter, similar to or the same as datacenter 1204.

As noted above, the datacenter 1204 and/or the network device(s) 1212 may include storage devices and/or processing circuitry for carrying out computing tasks, for example, tasks associated with controlling the flow of data internally and/or over the communication network 1208. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), an ASIC, combinations thereof, and the like. The processing circuitry may comprise an ASIC and/or may be capable of performing as a central processing unit (CPU), a graphics processing unit (GPU), a network interface card (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 1204 and network device(s) 1212 may include one or more communication interfaces for facilitating wired and/or wireless communication between one another and other unillustrated elements of the system 1200.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

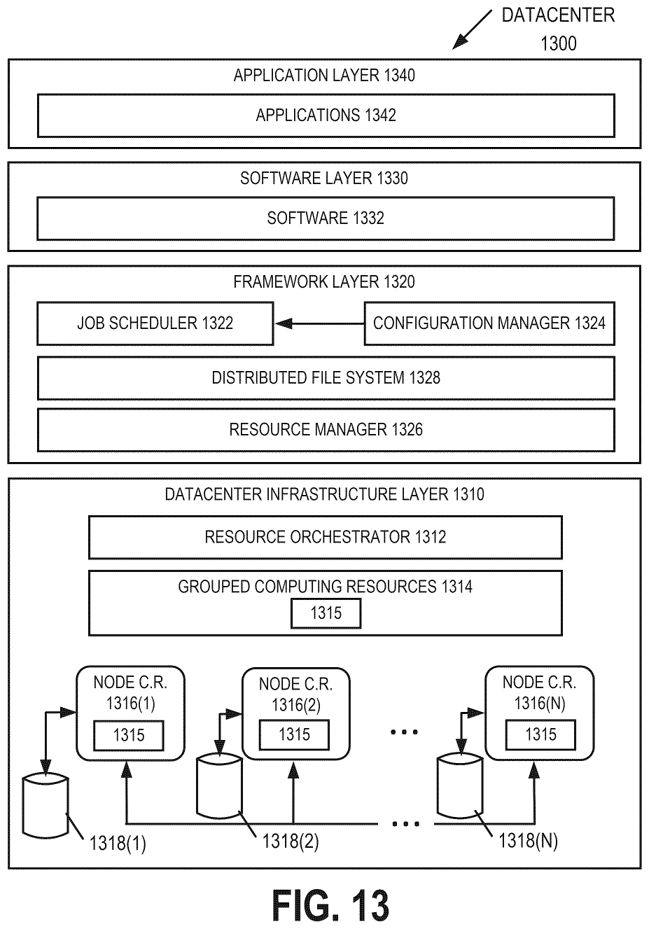

FIG. 13 illustrates an example datacenter 1300, in which at least one embodiment may be used. In at least one embodiment, datacenter 1300 includes a datacenter infrastructure layer 1310, a framework layer 1320, a software layer 1330, and an application layer 1340.

In at least one embodiment, as shown in FIG. 13, datacenter infrastructure layer 1310 may include a resource orchestrator 1312, grouped computing resources 1314, and node computing resources (“node C.R.s”) 1316(1)-1316(N), where “N” represents a positive integer (which may be a different integer “N” than used in other figures). In at least one embodiment, node C.R.s 1316(1)-1316(N) may include, but are not limited to, any number of central processing units (“CPUs”) or other processors (including accelerators, field programmable gate arrays (FPGAs), graphics processors, etc.), memory storage devices 1318(1)-1318(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1316(1)-1316(N) may be a server having one or more of above-mentioned computing resources.

In at least one embodiment, grouped computing resources 1314 may include separate groupings of node C.R.s housed within one or more racks (not shown), or many racks housed in datacenters at various geographical locations (also not shown). In at least one embodiment, separate groupings of node C.R.s within grouped computing resources 1314 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1312 may configure or otherwise control one or more node C.R.s 1316(1)-1316(N) and/or grouped computing resources 1314. In at least one embodiment, resource orchestrator 1312 may include a software design infrastructure (“SDI”) management entity for datacenter 1300. In at least one embodiment, resource orchestrator 1312 may include hardware, software or some combination thereof.

In at least one embodiment, as shown in FIG. 13, framework layer 1320 includes a job scheduler 1322, a configuration manager 1324, a resource manager 1326 and a distributed file system 1328. In at least one embodiment, framework layer 1320 may include a framework to support software 1332 of software layer 1330 and/or one or more application(s) 1342 of application layer 1340. In at least one embodiment, software 1332 or application(s) 1342 may respectively include web-based service software or applications, such as those provided by Amazon Web Services, Google Cloud and Microsoft Azure. In at least one embodiment, framework layer 1320 may be, but is not limited to, a type of free and open-source software web application framework such as Apache Spark™ (hereinafter “Spark”) that may utilize distributed file system 1328 for large-scale data processing (e.g., “big data”). In at least one embodiment, job scheduler 1322 may include a Spark driver to facilitate scheduling of workloads supported by various layers of datacenter 1300. In at least one embodiment, configuration manager 1324 may be capable of configuring different layers such as software layer 1330 and framework layer 1320 including Spark and distributed file system 1328 for supporting large-scale data processing. In at least one embodiment, resource manager 1326 may be capable of managing clustered or grouped computing resources mapped to or allocated for support of distributed file system 1328 and job scheduler 1322. In at least one embodiment, clustered or grouped computing resources may include grouped computing resources 1314 at datacenter infrastructure layer 1310. In at least one embodiment, resource manager 1326 may coordinate with resource orchestrator 1312 to manage these mapped or allocated computing resources.

In at least one embodiment, software 1332 included in software layer 1330 may include software used by at least portions of node C.R.s 1316(1)-1316(N), grouped computing resources 1314, and/or distributed file system 1328 of framework layer 1320. In at least one embodiment, one or more types of software may include, but are not limited to, Internet web page search software, e-mail virus scan software, database software, and streaming video content software.

In at least one embodiment, application(s) 1342 included in application layer 1340 may include one or more types of applications used by at least portions of node C.R.s 1316(1)-1316(N), grouped computing resources 1314, and/or distributed file system 1328 of framework layer 1320. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1324, resource manager 1326, and resource orchestrator 1312 may implement any number and type of self-modifying actions based on any amount and type of data acquired in any technically feasible fashion. In at least one embodiment, self-modifying actions may relieve a datacenter operator of datacenter 1300 from making possibly bad configuration decisions and possibly avoiding underutilized and/or poor performing portions of a datacenter.

In at least one embodiment, datacenter 1300 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1300. In at least one embodiment, trained machine learning models corresponding to one or more neural networks may be used to infer or predict information using resources described above with respect to datacenter 1300 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1315 are used to perform inferencing and/or training operations associated with one or more embodiments. In at least one embodiment, inference and/or training logic 1315 may be used in system FIG. 13 for inferencing or predicting operations based, at least in part, on weight parameters calculated using neural network training operations, neural network functions and/or architectures, or neural network use cases described herein.

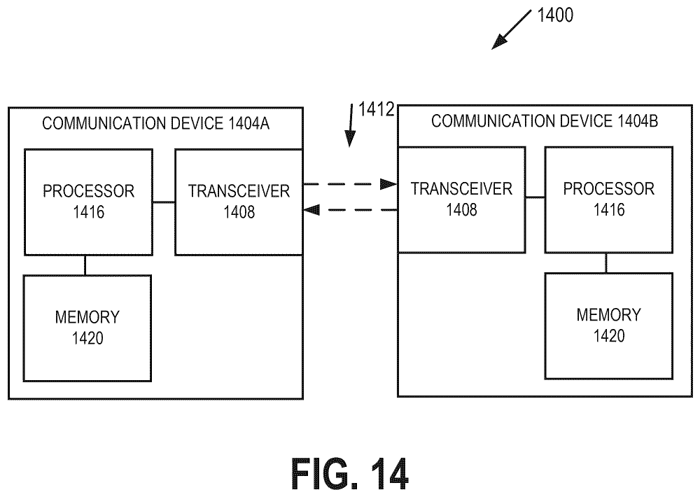

FIG. 14 illustrates a system 1400 including a first communication device 1404A and a second communication device 1404B. Illustratively, but without limitation, the communication devices 1404 (e.g., 1404A, 1404B) may correspond to network devices (e.g., network devices 1212). As such, the communication devices 1404 may correspond to any type of device that becomes part of or is connected with a communication network (e.g., communication network 1208). Examples of suitable devices that may act or operate like a communication device 1404 as described herein include, without limitation, one or more of a Personal Computer (PC), a laptop, a tablet, a smartphone, a server, a collection of servers, a networking card, an edge router, a switch, Network Interface Cards, a Top of Rack (ToR) switch, a server blade, or the like. The communication device 1404 may include a transceiver 1408, a processor 1416, and memory 1420. The transceiver 1408 may include hardware that enables communications over the communication channel 1412 whereas the processor 1416 and memory 1420 may include components that enable the communication device 1404 to provide a desired functionality or perform certain functions.

The communication channel 1412 may traverse a datacenter or any type of communication network (whether trusted or untrusted). Examples of a communication network that may be used to connect communication devices 1404 and support the communication channel 1412 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1404 using optical signals. In this case, the communication devices 1404 and the communication network may include waveguides (e.g., optical fibers) that carry the optical signals. For example, the communication devices and/or the communication network may include one or more systems 1100, according to various embodiments.

### CONCLUSION

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A frequency comb generator comprising:
a closed loop formed of gain material; and
an output waveguide,
wherein the closed loop formed of gain material is configured to provide an optical cavity for generating frequency comb pulses and the output waveguide is evanescently coupled to the optical cavity.

2. The frequency comb generator of claim 1, wherein the closed loop formed of gain material is formed on a substrate.

3. The frequency comb generator of claim 1, wherein gain material of the closed ring comprises at least one of quantum dots, quantum dashes, or quantum wells of a III-V semiconductor material.

4. The frequency comb generator of claim 1, wherein the frequency comb pulses comprise a plurality of spectral lines separated from one another by a line spacing.

5. The frequency comb generator of claim 1, further comprising a first electrode and a second electrode wherein the closed loop formed of gain material is disposed, at least in part, between the first electrode and the second electrode.

6. The frequency comb generator of claim 1, further comprising an anti-reflective coating applied to an output facet of the closed loop formed of gain material.

7. The frequency comb generator of claim 1, further comprising a waveguide grating disposed within the closed loop formed of gain material.

8. The frequency comb generator of claim 7, wherein the waveguide grating is configured to filter spectral lines present in the frequency comb pulses.

9. The frequency comb generator of claim 1, further comprising a saturable absorber disposed within the closed loop formed of gain material.

10. The frequency comb generator of claim 1, further comprising at least two saturable absorbers within the closed loop formed of gain material wherein the at least two saturable absorbers are evenly spaced about the closed loop formed of gain material the active optical cavity is configured for colliding pulse mode locking.

11. A frequency comb generator comprising:
a gain material section that extends along a gain axis from a first end to a second end, wherein the gain material section is configured to be an optical cavity for generating frequency comb pulses, the optical cavity is characterized by a section length, and a distance from the first end to the second end is greater than the section length; and
one or more dividers, wherein the one or more dividers divide the gain material section into two or more segments where each segment of the two or more segments has an optical length that is an integer multiple of the section length,
wherein at least one segment has a width in a direction perpendicular to the gain axis that is non-constant along a length of the at least one segment, the length being along the gain axis.

12. The frequency comb generator of claim 11, wherein the one or more dividers comprise at least one saturable absorber or at least one index gap.

13. The frequency comb generator of claim 11, further comprising a first confinement element disposed at the first end and a second confinement element disposed at the second end.

14. The frequency comb generator of claim 13, wherein the first confinement element is a mirror and the second confinement element is one of a mirror or a saturable absorber.

15. The frequency comb generator of claim 11, wherein the at least one segment having the width in the direction perpendicular to the gain axis that is non-constant along the length of the at least one segment is a tapered segment defined at least in part by a tapered boundary.

16. The frequency comb generator of claim 15, wherein the tapered boundary is one of a straight taper or an adiabatic taper.

17. The frequency comb generator of claim 11, wherein the second end of the gain material section is optically coupled to an output waveguide.

18. The frequency comb generator of claim 11, wherein one segment of the two or more segments has a waveguide grating formed therein configured to filter spectral lines present in the frequency comb pulses.

19. The frequency comb generator of claim 11, wherein the two or more segments are each configured to generate a selected harmonic mode of the gain material section such that the selected harmonic mode generated in adjacent segments of the two or more segments collide at a divider disposed between the adjacent segments to generate a primary mode of the gain material section.

20. A system comprising:
a substrate;
a frequency comb generator formed on the substrate, the frequency comb generator comprising one of:
a closed loop formed of gain material, or
a gain material section divided into two or more segments by one or more dividers, wherein at least one of the two or more segments is a tapered segment;
an output waveguide optically coupled to the frequency comb generator; and
one or more downstream elements, wherein the output waveguide provides frequency comb pulses generated by the frequency comb generator to the one or more downstream elements.

21. The system of claim 20, wherein at least one of the one or more downstream elements is configured to perform dense wavelength division multiplexing using the frequency comb pulses.

22. The system of claim 20, wherein at least one of:
the system is a transceiver; or
at least one of the one or more downstream elements is a transceiver in optical communication with the output waveguide via an optical interconnect.
